(19) United States
(12) Patent Application Publication
(10) Pub. No.: US 2020/0075735 A1
(43) Pub. Date: Mar. 5, 2020

(54) SEMICONDUCTOR DEVICE AND METHOD OF MANUFACTURING SEMICONDUCTOR DEVICE

(71) Applicant: FUJI ELECTRIC CO., LTD., Kawasaki-shi (JP)

(72) Inventor: Kosuke YOSHIDA, Matsumoto-city (JP)

(73) Assignee: FUJI ELECTRIC CO., LTD., Kawasaki-shi (JP)

(21) Appl. No.: 16/519,722

(22) Filed: Jul. 23, 2019

(30) Foreign Application Priority Data
Sep. 5, 2018 (JP) 2018-166234

(51) Int. Cl. H01L 29/40; H01L 21/765; H01L 29/78

(52) U.S. Cl. CPC H01L 29/407; H01L 29/7395; H01L 29/7811; H01L 21/765

(57) ABSTRACT

In an edge termination region, a trench is provided near a boundary of an active region. An embedded insulating film is embedded in the trench, and an inner FP and an outer FP are provided in the embedded insulating film. The inner FP extends from a center portion of the trench, upward and toward the active region and is curved in a protrusion-like shape that protrudes in a direction away from a side wall and a bottom of the trench. An upper end of the inner FP opposes an inner top corner portion of the trench, across the embedded insulating film or the interlayer insulating film. The upper end of the inner FP is positioned a predetermined distance from the front surface of the semiconductor substrate due to the embedded insulating film between the upper end of the inner FP and the front surface of the semiconductor substrate.

### CROSS REFERENCE TO RELATED APPLICATIONS

This application is based upon and claims the benefit of priority of the prior Japanese Patent Application No. 2018-166234, filed on Sep. 5, 2018, the entire contents of which are incorporated herein by reference.

### BACKGROUND OF THE INVENTION

### 1. Field of the Invention

Embodiments of the invention relate to a semiconductor device and a method of manufacturing a semiconductor device.

### 2. Description of the Related Art

Conventionally, in a discrete semiconductor device constituting a component of a semiconductor product, use of an edge termination region that surrounds a periphery of an active region as a termination structure (terminating structure) is commonly known (for example, refer to Published Japanese-Translation of PCT Application, Publication No. 2013-522909; Japanese Laid-Open Patent Publication No. 2017-168515; International Publication No. WO 2017/145197; and Wentao Yang, et al, “A New 1200V-class Edge Termination Structure with Trench Double Field Plates for High dV/dt Performance”, 2017 29th International Symposium on Power Semiconductor Devices and IC's:ISPSD, IEEE, May 30, 2017, p.109-112). A discrete semiconductor device is an independent semiconductor element that has a predetermined function such as a metal-insulator-semiconductor transistor (MIST) (transistor having a 3-layer structure constituted by a metal, an insulator, and a semiconductor), a diode, or an insulated gate bipolar transistor (IGBT).

The active region is a region through which current flows when internal elements are in an ON state. The edge termination region is a region between the active region and a side surface (chip edge) of the semiconductor substrate. The termination structure is a structure that equalizes electric potential of a rear surface of a semiconductor substrate (semiconductor chip) and electric potential of the side surface of the semiconductor substrate, the side surface being a cut surface where the semiconductor substrate is diced (cut) from a semiconductor wafer. The termination structure further prevents internal elements from being adversely affected electrically by mechanical damage due to dicing at the side surface of the semiconductor substrate. The termination structure of a conventional semiconductor device will be described. FIG. 34 is a cross-sectional view of a termination structure of a conventional semiconductor device. FIG. 34 corresponds to FIGS. 21A and 21B in International Publication No. WO 2017/145197.

The conventional semiconductor device depicted in FIG. 34 is, for example, an n-channel type vertical metal oxide semiconductor field effect transistor (MOSFET) that has an insulated gate having a 3-layer structure constituted by a metal, an oxide film, and a semiconductor material and that in an edge termination region 202 that surrounds a periphery of an active region 201, includes a termination structure constituted by an insulating film (hereinafter, embedded insulating film) 212 embedded in a trench 211 and field plates (FPs) 213, 214 embedded in the embedded insulating film 212. In FIG. 34, the structure from near a boundary between the active region 201 and the edge termination region 202, to a side surface of a semiconductor substrate 210 is depicted.

The trench 211 reaches a depth that from a front surface of the semiconductor substrate 210, is closer to an n⁺-type drain region 221 than is a depth of a pn junction 224 between a p-type region 223 and an n⁻-type drift region 222 in the active region 201. The trench 211 is disposed in a ring-shape surrounding a periphery of the active region 201. The FPs 213, 214 are disposed separated from each other in the embedded insulating film 212, at a depth that is shallower than a depth of a bottom 211c of trench 211. The FPs 213, 214 are disposed in the embedded insulating film 212, on opposing inner and outer sides toward the active region 201 and toward the side surface of the semiconductor substrate 210, respectively. Of the FPs 213, 214, the FP (hereinafter, inner FP) 213 is nearest the active region 201 and the FP (hereinafter, outer FP) 214 is nearest the side surface of the semiconductor substrate 210. The inner and outer FPs 213, 214 are disposed along side walls 211a, 211b of the trench 211, respectively, and surround a periphery of the active region 201.

The inner FP 213 extends toward the side wall 211a of the trench 211 and upward (toward a first metal wiring layer 227) from near a center of the trench 211 and has a curved portion of a protrusion-like shape protruding toward the bottom 211c so as to approach the side wall 211a. The inner FP 213 is electrically connected to the p-type region 223 via the first metal wiring layer 227 and a contact 226, and is fixed at an electric potential of a source electrode (not depicted). The outer FP 214 extends toward the side wall 211b of the trench 211 and upward (toward a second metal wiring layer 230) from near the center of the trench 211 and has a curved portion of a protrusion-like shape protruding toward the bottom 211c so as to approach the side wall 211b. The outer FP 214 is electrically connected to an n-type channel stopper region 228 via the second metal wiring layer 230 and a contact 229, and is designed to have an electric potential of a drain electrode 231.

The p-type region 223 functions as a back gate of the MOSFET. The p-type region 223 and the first metal wiring layer 227 are disposed further from the chip edge than is the trench 211. An end of the pn junction 224 terminates at the side wall 211a of the trench 211 and is exposed at the side wall 211a. The n-type channel stopper region 228 and the second metal wiring layer 230 are disposed closer to the chip edge than is the trench 211. The n-type channel stopper region 228 is exposed at the side wall 211b of the trench 211.

In the conventional n-channel type vertical MOSFET depicted in FIG. 34, the n⁺-type drain region 221 at a rear surface of the semiconductor substrate 210 and the side surface that includes a surface region (the n-type channel stopper region 228) that is a portion of the front surface of the semiconductor substrate 210 and closer to the chip edge than is the trench 211 have high electric potentials that are equal to that of the drain electrode 231. On the other hand, a surface region (the p-type region 223 and a non-depicted n⁺-type source region) that is a portion of the front surface of the semiconductor substrate 210 and further from the chip edge than is the trench 211 is at a ground potential (=0V) similarly to the source electrode. Therefore, a diode to handle a difference in the electric potential further from the chip edge than is the trench 211 and the electric potential closer to the chip edge than is the trench 211 is necessary at the surface region that is a portion of the front surface of the semiconductor substrate 210 and further from the chip edge than is the trench 211.

For example, in a diode using silicon (Si) as a semiconductor material, a length of the pn junction forming the diode has to be at minimum 40 μm for a breakdown voltage of 1200V, based on 30V/μm, which is breakdown field strength of a one-dimensional state for silicon. A typical diode is a two-dimensional structure and therefore, has a pn junction plane that is parallel to the front surface of the semiconductor substrate and electric field concentrates at a corner portion of the p-type region forming the pn junction plane. To mitigate the electric field at the corner portion of the p-type region, a length of the pn junction forming the diode, the length extending from an inner side toward an outer side in the semiconductor substrate, has to be longer than a length of a pn junction calculated based on the breakdown field strength of a one-dimensional state for silicon.

On the other hand, in the conventional termination structure depicted in the FIG. 34, the end of the pn junction 224 between the p-type region 223 of the active region 201 and the n⁻-type drift region 222 terminates at the embedded insulating film 212 in the trench 211. As a result, in a typical diode, equipotential lines in the semiconductor substrate and extending along the front surface of the semiconductor substrate, outward toward the chip edge may be set to be distributed from a front surface side of the semiconductor substrate 210, toward the n⁺-type drain region 221, mainly along the inner wall of the trench 211. In this manner, the equipotential lines in the semiconductor substrate 210 are in a depth direction from the front surface side of the semiconductor substrate 210, whereby a width of the edge termination region 202 may be reduced.

Usually, an insulating material has a breakdown field strength that is higher than that of silicon, whereby it is possible for a higher electric field to be handled in the embedded insulating film 212 than in the semiconductor substrate 210. Therefore, compared to a case where the trench 211 and the embedded insulating film 212 are not provided, in a state in which the breakdown voltage is sustained, it is possible to reduce the width of the edge termination region 202. Further, by extending the inner FP 213 to be separated from the side wall 211a of the trench 211 toward the chip edge with increasing depth from the front surface of the semiconductor substrate, equipotential line distribution in the depth direction along the side wall 211a of the trench 211 from the p-type region 223 becomes uniform in the semiconductor substrate 210. As a result, electric field concentration of a portion along the side wall 211a of the trench 211 is mitigated.

### SUMMARY OF THE INVENTION

According to an embodiment of the invention, a semiconductor device having an active region therein, includes a semiconductor substrate having a first main surface and a second main surface opposite to the first main surface, the semiconductor substrate including a first-conductivity-type region and a second-conductivity-type region that is disposed closer to the first main surface than is the first-conductivity-type region; a trench provided at a position closer to an outer periphery of the semiconductor substrate than is a position of the active region and reaching a predetermined depth from the first main surface of the semiconductor substrate, a pn junction between the first-conductivity-type region and the second-conductivity-type region extending from the active region toward the outer periphery of the semiconductor substrate and being terminated at the trench; a first insulating film embedded in the trench; a second insulating film provided on the second-conductivity-type region; a field plate extending along a depth direction in the first insulating film in the trench; a first electrode electrically connected to the second-conductivity-type region and the field plate; and a second electrode provided on the second main surface of the semiconductor substrate. The field plate has a first end at a position facing an upper end of an inner side wall of the trench and a second end at a position inside the first insulating film, the field plate extending from the inside the first insulating film toward the first main surface of the semiconductor substrate in the active region, and having a protrusion-like shape that protrudes in a direction away from the inner side wall and a bottom of the trench.

In the embodiment, the field plate has a curved portion forming the protrusion-like shape that protrudes in the direction away from the inner side wall and the bottom of the trench.

In the embodiment, the field plate has a first linear portion and a second linear portion, the first and second linear portions connecting to each other to form a right-angle at a connecting point of the first and second linear portions, and forming a substantially L-shape that protrudes in the direction away from the inner side wall and the bottom of the trench. The first linear portion extends in the first insulating film in the trench in the depth direction that is orthogonal to the first main surface of the semiconductor substrate. The second linear portion is provided at a position closer to the first main surface of the semiconductor substrate than is a position of the first linear portion, and extends in a direction parallel to the first main surface of the semiconductor substrate toward the active region.

In the embodiment, a breakdown voltage during breakdown at a lower end of the inner side wall of the trench is higher than a breakdown voltage during the breakdown at the pn junction.

In the embodiment, the first-conductivity-type region has a resistivity of 145 Ω·cm or less.

In the embodiment, each of the first insulating film and the second insulating film is a silicon oxide film.

According to another embodiment, a method of manufacturing a semiconductor device having an active region therein, includes forming a semiconductor substrate including a first-conductivity-type region and a second-conductivity-type region on the first-conductivity-type region, to form a pn junction between the first-conductivity-type region and the second-conductivity-type region, the pn junction extending toward an outer periphery of the device from the active region; forming a trench at a position closer to the outer periphery of the device than is a positon of the active region, to reach a predetermined depth from the first main surface of the semiconductor substrate and terminate the pn junction; depositing a first oxide film on the first main surface of the semiconductor substrate by a chemical vapor deposition method to embed the first oxide film in the trench; etching the first oxide film to leave the first oxide film of a predetermined thickness on the first main surface of the semiconductor substrate, and the first oxide film in the trench; forming a conductive film along a surface of the first oxide film; selectively removing the conductive film to leave a portion thereof toward the active region as a field plate; and embedding a second oxide film in the trench to cover the field plate by the second oxide film.

In the embodiment, the field plate has a first end at a position facing an upper end of an inner side wall of the trench and a second end at a position inside the first oxide film, the field plate having a protrusion-like shape that protrudes in a direction away from the inner side wall and a bottom of the trench.

In the embodiment, the semiconductor substrate is of a first conductivity type and has a resistivity that is at most 145 Ω·cm, and forming the pn junction includes forming the second-conductivity-type region in a surface layer of the first-conductivity-type region.

According to another embodiment, a method of manufacturing a semiconductor device having an active region therein, includes forming a semiconductor substrate including a first-conductivity-type region and a second-conductivity-type region on the first-conductivity-type region, to form a pn junction between the first-conductivity-type region and the second-conductivity-type region, the pn junction extending toward an outer periphery of the device from the active region; forming a trench at a position closer to the outer periphery of the device than is a positon of the active region, to reach a predetermined depth from a first main surface of the semiconductor substrate and terminate the pn junction; depositing a first oxide film on the first main surface of the semiconductor substrate by a chemical vapor deposition method to embed the first oxide film in the trench; polishing a surface of the first oxide film to be parallel to the first main surface of the semiconductor substrate, to leave the first oxide film in the trench from the first main surface of the semiconductor substrate; forming in the trench, a groove that has a width narrower than a width of the trench and that extends in the first oxide film in a depth direction orthogonal to the surface of the first oxide film; depositing a conductive film on the surface of the first oxide film to embed the conductive film in the groove; selectively removing the conductive film to leave a portion thereof as a field plate in the first oxide film, the field plate having a first linear portion remaining in the groove, and the second linear portion connected to the first linear portion and extending along the surface of the first oxide film toward the active region; and depositing a second oxide film on the surface of the first oxide film to cover the field plate.

In the embodiment, the field plate has a first end at a position facing an upper end of an inner side wall of the trench, and a second end at a position inside the first oxide film and has a protrusion-like shape that protrudes in a direction away from the inner side wall and a bottom of the trench.

In the embodiment, the semiconductor substrate is of a first conductivity type and has a resistivity that is at most 145 Ω·cm, and forming the pn junction includes forming the second-conductivity-type region in a surface layer of the first-conductivity-type region.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view of a termination structure of a semiconductor device according to a first embodiment.

FIG. 2 is a cross-sectional view of the semiconductor device according to the first embodiment during manufacture.

FIG. 3 is a cross-sectional view of the semiconductor device according to the first embodiment during manufacture.

FIG. 4 is a cross-sectional view of the semiconductor device according to the first embodiment during manufacture.

FIG. 5 is a cross-sectional view of the semiconductor device according to the first embodiment during manufacture.

FIG. 6 is a cross-sectional view of the semiconductor device according to the first embodiment during manufacture.

FIG. 7 is a cross-sectional view of the semiconductor device according to the first embodiment during manufacture.

FIG. 8 is a cross-sectional view of the semiconductor device according to the first embodiment during manufacture.

FIG. 9 is a cross-sectional view of the semiconductor device according to the first embodiment during manufacture.

FIG. 10 is a cross-sectional view of the semiconductor device according to the first embodiment during manufacture.

FIG. 11 is a cross-sectional view of the semiconductor device according to the first embodiment during manufacture.

FIG. 12 is a cross-sectional view of the semiconductor device according to the first embodiment during manufacture.

FIG. 13 is a cross-sectional view of the semiconductor device according to the first embodiment during manufacture.

FIG. 14 is a cross-sectional view of the termination structure of the semiconductor device according to a second embodiment.

FIG. 15 is a cross-sectional view of the semiconductor device according to the second embodiment during manufacture.

FIG. 16 is a cross-sectional view of the semiconductor device according to the second embodiment during manufacture.

FIG. 17 is a cross-sectional view of the semiconductor device according to the second embodiment during manufacture.

FIG. 18 is a cross-sectional view of the semiconductor device according to the second embodiment during manufacture.

FIG. 19 is a cross-sectional view of the semiconductor device according to the second embodiment during manufacture.

FIG. 20 is a cross-sectional view of the semiconductor device according to the second embodiment during manufacture.

FIG. 21 is a cross-sectional view of the semiconductor device according to the second embodiment during manufacture.

FIG. 22 is a cross-sectional view of the semiconductor device according to the second embodiment during manufacture.

FIG. 23 is a diagram depicting equipotential line distribution of an edge termination region of a first example.

FIG. 24 is a diagram depicting equipotential line distribution of an edge termination region of a second example.

FIG. 25 is a diagram depicting equipotential line distribution of an edge termination region of a conventional example.

FIG. 26 is a diagram depicting electric field distribution of the edge termination region of the first example.

FIG. 27 is a diagram depicting electric field distribution of the edge termination region of the second example.

FIG. 28 is diagram depicting electric field distribution of an edge termination region of a conventional example.

FIG. 29 is a diagram depicting equipotential line distribution of an edge termination region in a third example.

FIG. 30 is a diagram depicting electric field distribution of the edge termination region in the third example.

FIG. 31 is a diagram depicting equipotential line distribution of an edge termination region in a comparison example.

FIG. 32 is a diagram of electric field distribution of the edge termination region in the comparison example.

FIG. 33 is a diagram depicting a relationship of resistivity of a drift region and breakdown voltage.

FIG. 34 is a cross-sectional view of a termination structure of a conventional semiconductor device.

### DETAILED DESCRIPTION OF THE INVENTION

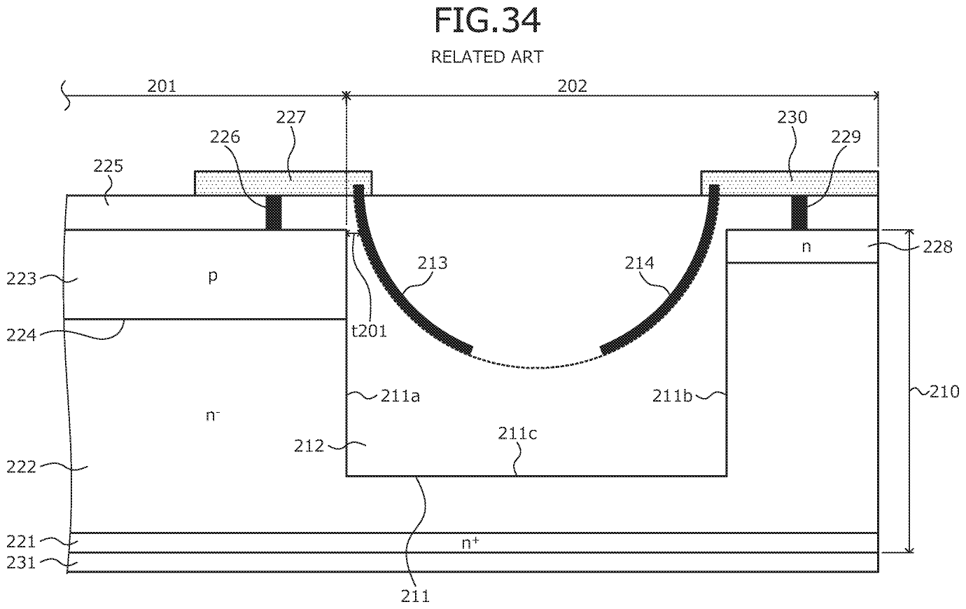

First, problems associated with the conventional techniques will be discussed. In the conventional termination structure depicted in FIG. 34 and described above, benzocyclobutene (BCB) is used as an insulating material of the embedded insulating film 212. BCB has a breakdown field strength of 530V/μm. A silicon oxide (SiO₂) film generally used as an insulating material of a semiconductor device has a breakdown field strength of 1000V/μm. Use of BCB as the insulating material of the embedded insulating film 212, for example, is less effective in reducing a width of the embedded insulating film 212 (i.e., the width of the trench 211), as compared to a case where a general oxide film is used as the insulating material of the embedded insulating film 212.

Furthermore, BCB is an organic coating material. Therefore, in the trench 211, which has the side walls 211a, 211b that are orthogonal to the front surface of the semiconductor substrate 210, a surface (upper surface) of the embedded insulating film 212 constituted by the BCB that is embedded not completely filling the trench 211 has semicircular shape (indicated by dashed line) curved so as to protrude toward the bottom 211c of trench 211. Both the inner FP 213 and the outer FP 214 are formed along the curved surface of the embedded insulating film 212 and therefore, have a cross-sectional shape curved in a protrusion-like shape protruding toward the bottom 211c so as to approach the side walls 211a, 211b of the trench 211.

When the inner FP 213 is curved in this manner, a distance t201 from an inner top corner portion of the trench 211 (the top corner portion nearest the inner FP 213) to the inner FP 213 is short, whereby spreading of a depletion layer at the side wall 211a of the trench 211 at the p-type region 223 in the active region 201 is adversely affected by the electric potential of the inner FP 213 and becomes difficult, thereby increasing the electric field at the side wall 211a of the trench 211. The inner top corner portion of the trench 211 is a boundary between the front surface of the semiconductor substrate 210 and the side wall 211a of the trench 211. The breakdown voltage of the diode formed at the pn junction 224 between the p-type region 223 and the n⁻-type drift region 222 decreases due to the increased electric field and a problem arises in that breakdown capability of the element decreases.

Embodiments of a semiconductor device and a method of manufacturing a semiconductor device according to the present invention will be described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments below and the accompanying drawings, main portions that are identical will be given the same reference numerals and will not be repeatedly described.

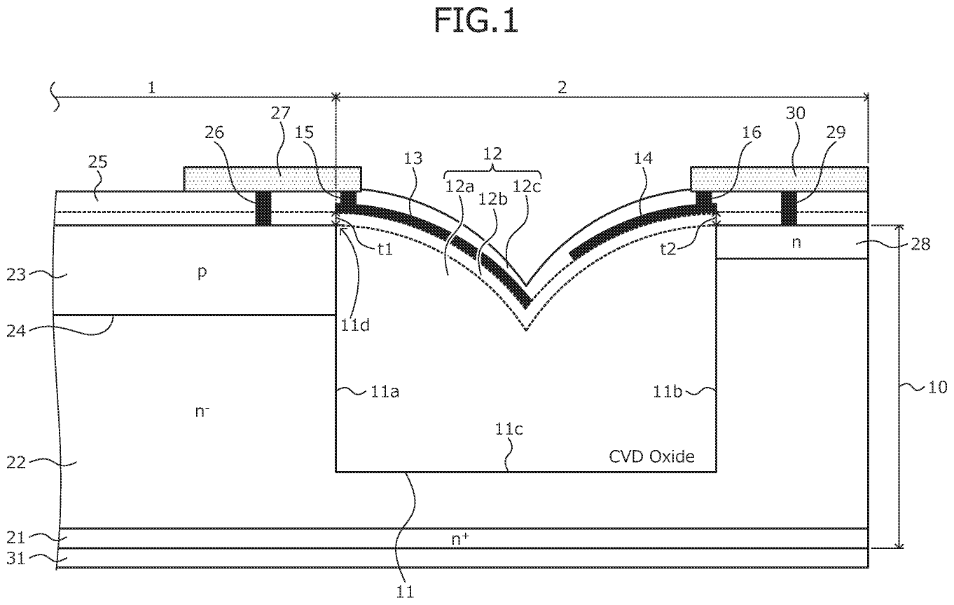

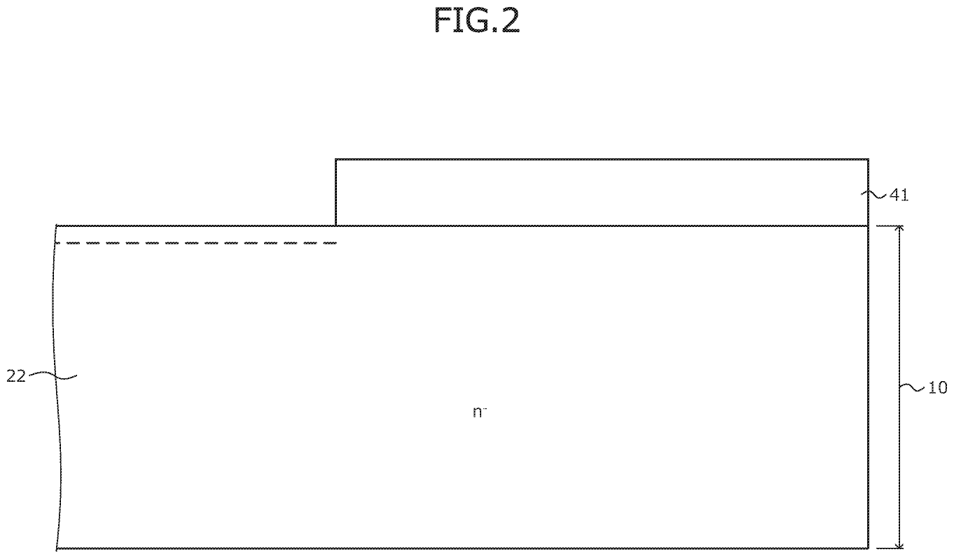

A termination structure of a semiconductor device according to a first embodiment will be described taking an n-channel type vertical MOSFET as an example. FIG. 1 is a cross-sectional view of the termination structure of the semiconductor device according to the first embodiment. In FIG. 1, a structure from near a boundary between an active region 1 and an edge termination region 2 to a side surface of a semiconductor substrate 10 is depicted (similarly in FIGS. 2 to 22). The semiconductor device according to the first embodiment and depicted in FIG. 1 includes the termination structure in the edge termination region 2 that surrounds a periphery of the active region 1. The termination structure includes a trench 11 formed to have ring-like planar shape so as to surround a periphery of the active region 1, and an insulating film (embedded insulating film) 12 embedded in the trench 11. The termination structure further includes inner and outer field plates (FPs) 13, 14 that respectively extend from upper portions of side walls of the trench 11 into the embedded insulating film 12. The inner and outer FPs 13, 14 are also formed to have a ring-like planar shape so as to surround a periphery of the active region 1.

The active region 1 is a region of the semiconductor substrate (semiconductor chip) 10, through which current flows when the MOSFET is in an ON state. The active region 1, for example, is disposed at a center portion of the semiconductor substrate 10. While not depicted, the active region 1, for example, has a substantially rectangular planar shape. In the active region 1, a non-depicted general MOS gate structure is provided and constituted by a p-type region (second-conductivity-type region) 23, an n⁺-type source region, a p⁺-type contact region, a gate insulating film, and a gate electrode. The semiconductor substrate 10 is of an n⁻-type. Further, in a surface layer at a rear surface of the semiconductor substrate 10, an n⁺-type drain region 21 is provided spanning the rear surface of the semiconductor substrate 10.

A portion of the semiconductor substrate 10 other than the n⁺-type drain region 21 and regions constituting a MOS gate structure constitutes an n⁻-type drift region (first-conductivity-type region) 22. The p-type region 23 is provided in a surface layer at the front surface of the semiconductor substrate 10, in the active region 1. The p-type region 23 functions as a p-type base region of an n-channel type MOSFET or a back gate disposed in a p-channel type MOSFET. FIG. 1 depicts the p-type region 23 that of one or more unit cells (constituent units of an element) of the MOSFET disposed in the active region 1, constitutes the unit cell that is furthest outward (nearest the side surface of the semiconductor substrate 10).

A parasitic diode is formed at a pn junction 24 between the p-type region 23 and the n⁻-type drift region 22. The pn junction 24 extends from the active region 1 to the edge termination region 2. An end of the pn junction 24 terminates at an inner side wall 11a (the side wall that is nearest the center portion of the semiconductor substrate 10) of the trench 11 in the edge termination region 2 and is exposed at the inner side wall 11a of the trench 11. The parasitic diode formed at the pn junction 24 has a function of handling a difference in electric potential closer to the center portion of the semiconductor substrate 10 than is the trench 11 and electric potential closer to the side surface of the semiconductor substrate 10 than is the trench 11, at a surface region (the p-type region 23 and a non-depicted n⁺-type source region) that is at the front surface of the semiconductor substrate 10 and closer to the center portion of the semiconductor substrate 10 than is the trench 11.

The pn junction 24 between the p-type region 23 and the n⁻-type drift region 22 is in contact with the embedded insulating film 12 at the inner side wall 11a of the trench 11 and terminates at the inner side wall 11a, whereby the outer end of the pn junction 24 substantially does not curve. Therefore, electric field does not concentrate at the outer end of the pn junction 24 between the p-type region 23 and the n⁻-type drift region 22. As a result, the trench 11 has an optimal depth and an optimal width, whereby breakdown voltage that is about equal to a theoretical value of a maximum breakdown voltage (maximum withstand voltage) obtained by the pn junction 24 between the p-type region 23 and the n⁻-type drift region 22 is obtained. Breakdown voltage is a voltage limit at which no errant operation or destruction of the element occurs.

An interlayer insulating film 25 covers the front surface of the semiconductor substrate 10 entirely. The interlayer insulating film 25, for example, is formed concurrently with oxide films 12b, 12c that constitute a portion of the embedded insulating film 12. The p-type region 23 is electrically connected to a non-depicted source electrode via a non-depicted contact (electrical contact) that penetrates the interlayer insulating film 25 in the depth direction (vertical direction). The p-type region 23 is further electrically connected to a first metal wiring layer 27 (first electrode) via a first contact 26 that penetrates the interlayer insulating film 25 in the depth direction. The first metal wiring layer 27 is provided separated from the source electrode and closer to the side surface of the semiconductor substrate 10 than is the source electrode.

The p-type region 23, the first contact 26, and the first metal wiring layer 27 are disposed closer to the center portion of the semiconductor substrate 10 than is the trench 11. An inner portion that includes the p-type region 23 that is connected to the first contact 26 is the active region 1. The first contact 26 may be, for example, formed using a metal material identical to that of the first metal wiring layer 27, or may be a contact structure aimed at size reduction of the unit cell of the MOSFET similarly to a source contact of the MOSFET. A contact structure aimed at size reduction of the unit cell of the MOSFET is a contact structure constituted by a tungsten (W) plug that via a barrier metal, is embedded in a contact hole that penetrates the interlayer insulating film 25 in the depth direction.

The first metal wiring layer 27 is provided on the interlayer insulating film 25, in a ring-shape surrounding a periphery of the active region 1 and covering the first contact 26. The first metal wiring layer 27 extends on the interlayer insulating film 25, from a connection site with the first contact 26, in a direction toward the center portion and a direction toward the side surface of the semiconductor substrate 10. The first metal wiring layer 27 is fixed at an electric potential of the source electrode via the p-type region 23. The first metal wiring layer 27 functions as an anode electrode of the parasitic diode at the pn junction 24 between the p-type region 23 and the n⁻-type drift region 22. The first metal wiring layer 27 is configured by a metal material, for example, identical to that of the source electrode.

The edge termination region 2 is a region between the active region 1 and the side surface of the semiconductor substrate 10. In the edge termination region 2, an n-type channel stopper region 28 is selectively provided in the surface layer at the front surface of the semiconductor substrate 10. The n-type channel stopper region 28 is exposed at the side surface of the semiconductor substrate 10 and is exposed at an outer side wall 11b (the side wall that is nearest the side surface of the semiconductor substrate 10) of the trench 11. The n-type channel stopper region 28 is electrically connected to a second metal wiring layer 30 via a second contact 29 that penetrates the interlayer insulating film 25 in the depth direction. The n-type channel stopper region 28, the second contact 29, and the second metal wiring layer 30 are disposed closer to the side surface of the semiconductor substrate 10 than is the trench 11.

The n-type channel stopper region 28 may be omitted. In this case, the outer FP 14 is connected to the n⁻-type drift region 22 via the second metal wiring layer 30 and the second contact 29. Further, instead of the n-type channel stopper region 28, a p-type diffusion layer may be provided. In this case, the outer FP 14 is connected to a channel stopper region constituted by the p-type diffusion layer, via the second metal wiring layer 30 and the second contact 29 (not depicted).

Configuration of the second contact 29 may be, for example, similar to that of the first contact 26. The second metal wiring layer 30 is provided on the interlayer insulating film 25, in a ring-shape surrounding a periphery of the trench 11 and covering the second contact 29. The second metal wiring layer 30 extends on the interlayer insulating film 25, from a connection site with the second contact 29, in a direction toward the center portion and a direction toward the side surface of the semiconductor substrate 10. The second metal wiring layer 30 is fixed at an electric potential of a drain electrode 31 (second electrode) via the n-type channel stopper region 28. Configuration of the second metal wiring layer 30 may be, for example, similar to that of the first metal wiring layer 27. The drain electrode 31 is provided at the rear surface of the semiconductor substrate 10 overall.

Further, in the edge termination region 2, the trench 11 is provided from the front surface of the semiconductor substrate 10 to a depth that does not reach the n⁺-type drain region 21. The trench 11 is disposed between the p-type region 23 of the active region 1 and the n-type channel stopper region 28. The trench 11 penetrates the p-type region 23 and the n-type channel stopper region 28 from the front surface of the semiconductor substrate 10 and reaches a depth closer to the n⁺-type drain region 21 than is a depth of the pn junction 24 between the p-type region 23 and the n⁻-type drift region 22. The trench 11 is disposed in a ring-shape surrounding a periphery of the active region 1. The embedded insulating film 12 is embedded in the trench 11.

The embedded insulating film 12 is an oxide film that has a breakdown field strength higher than that of an organic coating material and, for example, is deposited by a chemical vapor deposition (CVD) method. By forming the embedded insulating film 12 using an oxide film deposited by a CVD method, at a surface of the embedded insulating film 12, a portion recessed toward a bottom 11c occurs near a center of the trench 11. The portion has a substantially V-shaped cross-sectional shape that has curved portions each forming a protrusion that with increasing proximity to each of the inner and the outer side walls 11a, 11b of the trench 11 from the recessed portion, protrude in directions away from the inner and the outer side walls 11a, 11b and the bottom 11c of the trench 11.

Along the surface of the embedded insulating film 12, the inner and outer FPs 13, 14 are formed having shapes substantially identical to that of the surface of the embedded insulating film 12. In FIG. 1, dashed lines in the embedded insulating film 12 represent boundaries of oxide films 12a to 12c that constitute the embedded insulating film 12 that when the inner and outer FPs 13, 14 are embedded in the embedded insulating film 12, is deposited in stages (here, 3 stages) in the trench 11 as described hereinafter. The oxide film (in FIG. 1, “CVD Oxide”) deposited by a CVD method is, for example, a silicon oxide (SiO₂) film capable of realizing breakdown field strength of about 1000V/μm.

The inner and outer FPs 13, 14 are embedded in the embedded insulating film 12. The inner and outer FPs 13, 14 are disposed separated from each other at positions shallower than the bottom 11c of the trench 11. The inner and outer FPs 13, 14 are respectively disposed in the embedded insulating film 12, on an inner side (side nearest the active region 1) and an outer side (side nearest the side surface of the semiconductor substrate 10). The inner FP 13 that is closer to the active region 1 than is the outer FR 14 and the outer FP 14 that is closer to the side surface of the semiconductor substrate 10 than is the inner FP 13 surround a periphery of the active region 1, along the inner and the outer side walls 11a, 11b of the trench 11, respectively. The inner FP 13 and the outer FP 14 oppose each other across the embedded insulating film 12, in a direction from the active region 1 toward the side surface of the semiconductor substrate 10.

The inner FP 13 extends from near a center portion of the trench 11 toward the active region 1 and upward (toward the front surface of the semiconductor substrate 10) and has a curved portion of a protrusion-like shape protruding in a direction away from the inner side wall 11a and the bottom 11c of the trench 11. An upper end (first end) of the inner FP 13 opposes an inner top corner portion 11d (the top corner portion nearest the active region 1) of the trench 11, across the embedded insulating film 12 or the interlayer insulating film 25. The upper end (second end) of the inner FP 13 is positioned to be separated from the front surface of the semiconductor substrate 10 by a predetermined distance t1, by the embedded insulating film 12 or the interlayer insulating film 25 therebetween. The inner top corner portion 11d of the trench 11 is a boundary that is between the front surface of the semiconductor substrate 10 and the inner side wall 11a of the trench 11 and that constitutes an upper end of the inner side wall 11a of the trench 11.

Further, the upper end of the inner FP 13 is electrically connected to an outer end of the first metal wiring layer 27 via a third contact 15 that penetrates the interlayer insulating film 25 in the depth direction. A lower end (end toward the drain electrode 31) of the inner FP 13 may reach a depth as deep as possible in the embedded insulating film 12. The inner FP 13 is electrically connected to the p-type region 23 via the first metal wiring layer 27 and is fixed at the electric potential of the source electrode. The inner FP 13 may be, for example, a poly-silicon (poly-Si) film, or an aluminum (Al) film deposited by sputtering.

The third contact 15 may be configured of a same material as that of the inner FP 13 or the first contact 26. The upper end of the inner FP 13 may be in direct contact with the outer end of the first metal wiring layer 27 without provision of the third contact 15. For example, the first metal wiring layer 27 is embedded in a contact hole that penetrates the interlayer insulating film 25 in the depth direction, whereby the first metal wiring layer 27 and the first contact 26 are formed by the same material. In this case, the upper end of the inner FP 13 extends toward the active region 1 so as to be exposed at a side wall of the contact hole and is in direct contact with the first contact 26, at the side wall of the contact hole.

The outer FP 14 extends outward toward the side surface of the semiconductor substrate 10 and upward (toward the front surface of the semiconductor substrate 10), from a position closer to the side surface of the semiconductor substrate 10 than is the center portion of the trench 11. The outer FP 14 has a curved portion of a protrusion-like shape protruding in a direction away from the outer side wall 11b and the bottom 11c of the trench 11. An upper end of the outer FP 14 opposes an outer top corner portion of the trench 11, across the interlayer insulating film 25 in the depth direction. The upper end of the outer FP 14 is positioned to be separated from the front surface of the semiconductor substrate 10 by a predetermined distance t2, by the embedded insulating film 12 or the interlayer insulating film 25 therebetween. The outer top corner portion of the trench 11 is the boundary between the front surface of the semiconductor substrate 10 and the outer side wall 11b of the trench 11.

Further, the upper end of the outer FP 14 is electrically connected to an inner end of the second metal wiring layer 30 via a fourth contact 16 that penetrates the interlayer insulating film 25 in the depth direction. Similarly to the inner FP 13, the upper end of the outer FP 14 may be in direct contact with the inner end of the second metal wiring layer 30 without provision of the fourth contact 16. The outer FP 14 is electrically connected to the n-type channel stopper region 28 via the second metal wiring layer 30 and is fixed at the electric potential of the drain electrode 31. The outer FP 14 and the fourth contact 16 may be configured by materials similar to those of the inner FP 13 and the third contact 15, respectively.

A method of manufacturing the semiconductor device according to the first embodiment will be described. FIGS. 2, 3, 4, 5, 6, 7, 8, 9, 10, 11, 12, and 13 are cross-sectional views of the semiconductor device according to the first embodiment during manufacture. First, as depicted in FIG. 2, the semiconductor substrate (semiconductor wafer) 10 constituting the n⁻-type drift region 22 is prepared. Next, on the front surface of the semiconductor substrate 10, an ion implantation mask 41 is formed that is opened at portions corresponding to a formation region of the p-type region 23 constituting a back gate, a p-type base region, etc. of the MOSFET. Next, the ion implantation mask 41 is used as a mask and, for example, a p-type impurity such as boron (B) is ion implanted. In FIG. 2, the p-type impurity that is ion implanted in the semiconductor substrate 10 is depicted by a dashed line. Subsequently, the ion implantation mask 41 is removed.

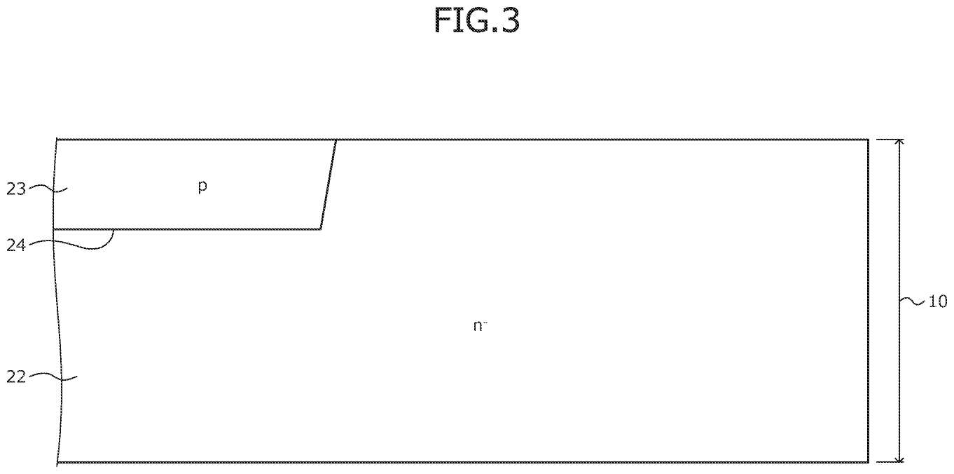

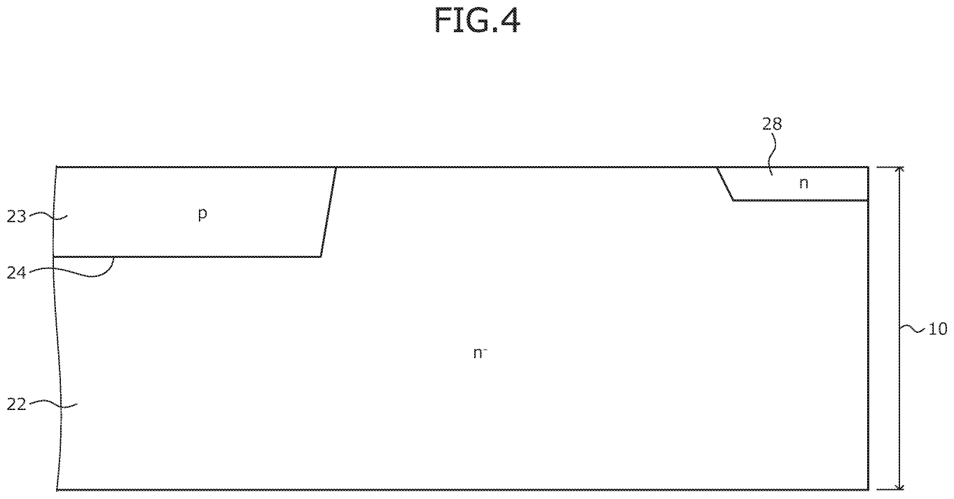

Next, as depicted in FIG. 3, the p-type impurity that is ion implanted in the semiconductor substrate 10 is activated by a heat treatment, whereby the p-type region 23 is selectively formed in the surface layer at the front surface of the semiconductor substrate 10 (first process). Next, on the front surface of the semiconductor substrate 10, an ion implantation mask (not depicted) is formed that is opened at portions corresponding to a formation region of the n-type channel stopper region 28. Next, the ion implantation mask is used as a mask and, for example, an n-type impurity such as phosphorus (P) is ion implanted. Next, after the ion implantation mask is removed, as depicted in FIG. 4, the n-type impurity that is ion implanted in the semiconductor substrate 10 is activated by a heat treatment, whereby the n-type channel stopper region 28 is selectively formed in the surface layer at the front surface of the semiconductor substrate 10. When a p-type channel stopper region is formed instead of the n-type channel stopper region 28, a p-type impurity is ion implanted and activated instead ion implanted an n-type impurity.

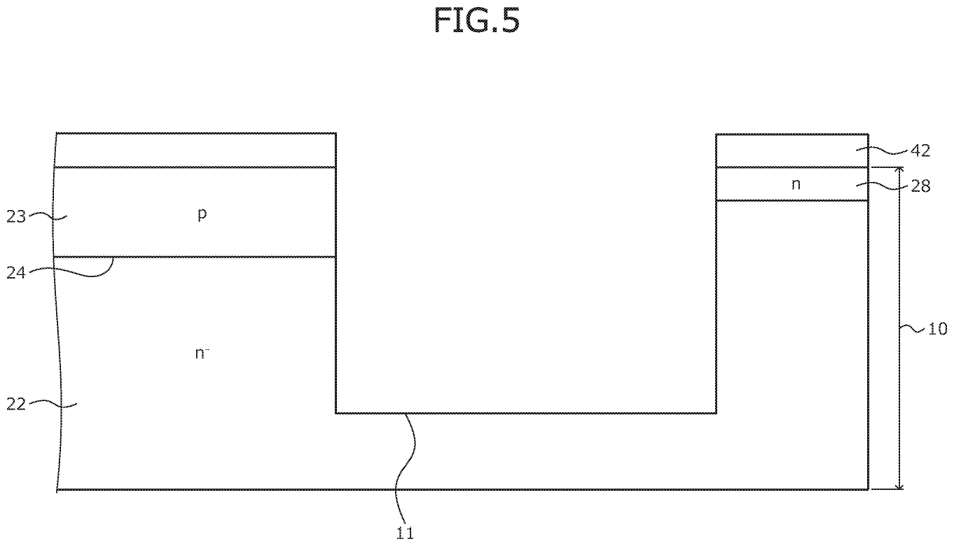

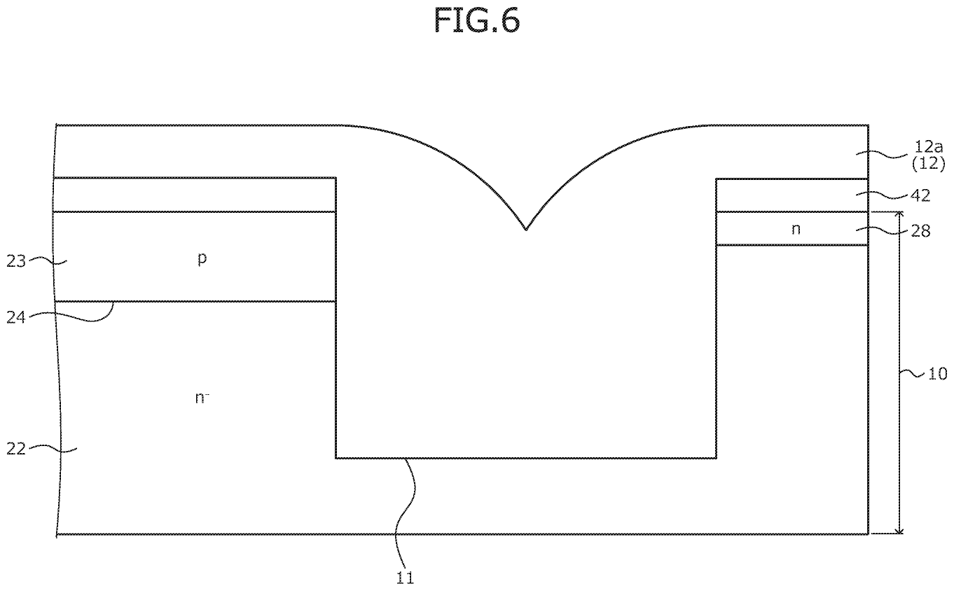

Next, as depicted in FIG. 5, on the front surface of the semiconductor substrate 10, for example a silicon nitride (SiN) film 42 is formed. Next, the silicon nitride film 42 is selectively removed to expose portions of the semiconductor substrate 10 corresponding to a formation region of the trench 11. Next, remaining portions of the silicon nitride film 42 are used as a mask and etching is performed, whereby the trench 11 is formed to penetrate the p-type region 23 and the n-type channel stopper region 28 from the front surface of the semiconductor substrate 10 and reach a predetermined depth (second process). Next, as depicted in FIG. 6, the oxide film (first oxide film) 12a constituting the embedded insulating film 12 is deposited by a CVD method and the trench 11 is completely embedded with the oxide film 12a (third process). Here, the oxide film 12a is further deposited on a surface of the silicon nitride film 42.

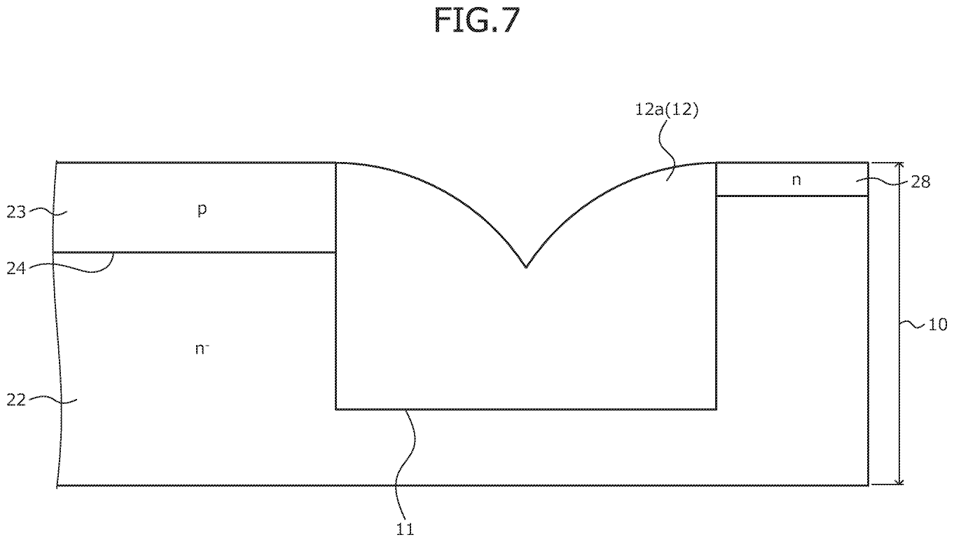

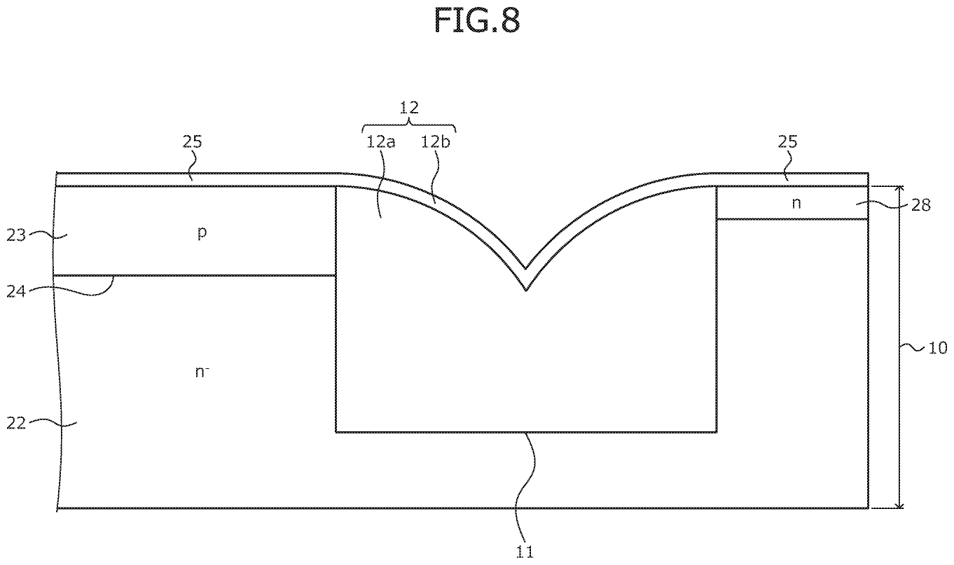

Next, as depicted in FIG. 7, the oxide film 12a and the silicon nitride film 42 are etched until the front surface of the semiconductor substrate 10 is exposed. As a result, the oxide film 12a remains only in the trench 11 (fourth process). A surface of the oxide film 12a has a cross-sectional shape that is similar to that of the surface of the embedded insulating film 12 after completion. Next, as depicted in FIG. 8, on the front surface of the semiconductor substrate 10 and the oxide film 12a, the oxide film (first oxide film) 12b constituting the embedded insulating film 12 is deposited by a CVD method so as to cover the oxide film 12a. A portion of the oxide film 12b covered by the oxide film 12a constitutes the embedded insulating film 12, portions covering the p-type region 23 and the n-type channel stopper region 28 constitute the interlayer insulating film 25. A surface of the oxide film 12b above the trench 11 has a cross-sectional shape that is substantially identical to that of the surface of the oxide film 12a therebelow. After the silicon nitride film 42 is removed, the oxide film 12a may be deposited and the oxide film 12a may be etched so that the oxide film 12a remains in the trench 11 and on the front surface of the semiconductor substrate 10. In this case, a process of depositing the oxide film 12b may be omitted.

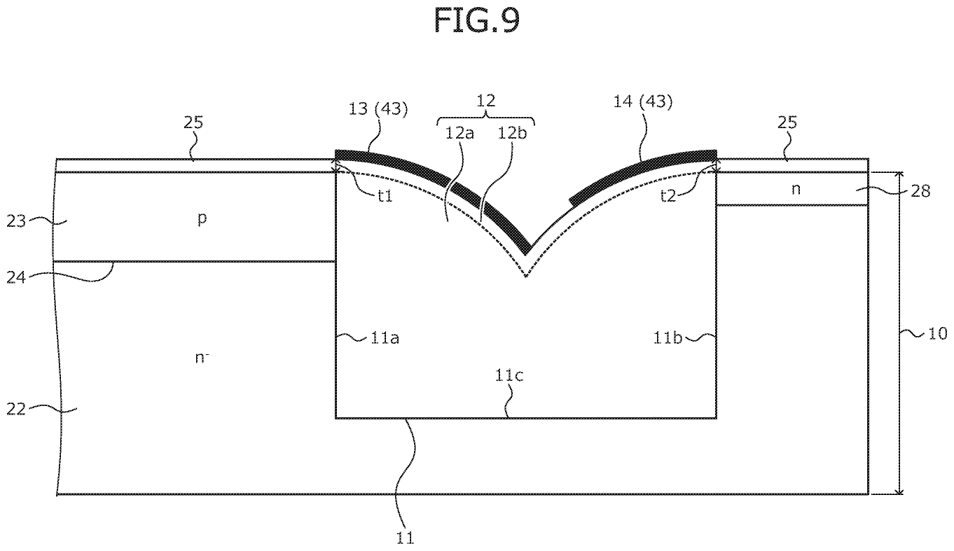

Next, as depicted in FIG. 9, on the oxide film 12b, a conductive film 43 is formed along the surface of the oxide film 12b by, for example, sputtering aluminum or depositing poly-silicon (fifth process). Next, the conductive film 43 is patterned so that portions of the conductive film 43 constituting the inner FP 13 and the outer FP 14 remain (sixth process). A surface of the conductive film 43 has a cross-sectional shape that is substantially identical to that of the surface of the oxide film 12b therebelow. Therefore, the inner FP 13 is formed so as to be curved in a protrusion-like shape that protrudes in a direction away from the inner side wall 11a and the bottom 11c of the trench 11. The outer FP 14 is formed so as to be curved in a protrusion-like shape that protrudes in a direction away from the outer side wall 11b and the bottom 11c of the trench 11. The inner FP 13 and the outer FP 14 are formed at positions separated from the front surface of the semiconductor substrate 10 by the predetermined distances t1, t2, respectively, and have thicknesses equal to that of the oxide film 12b.

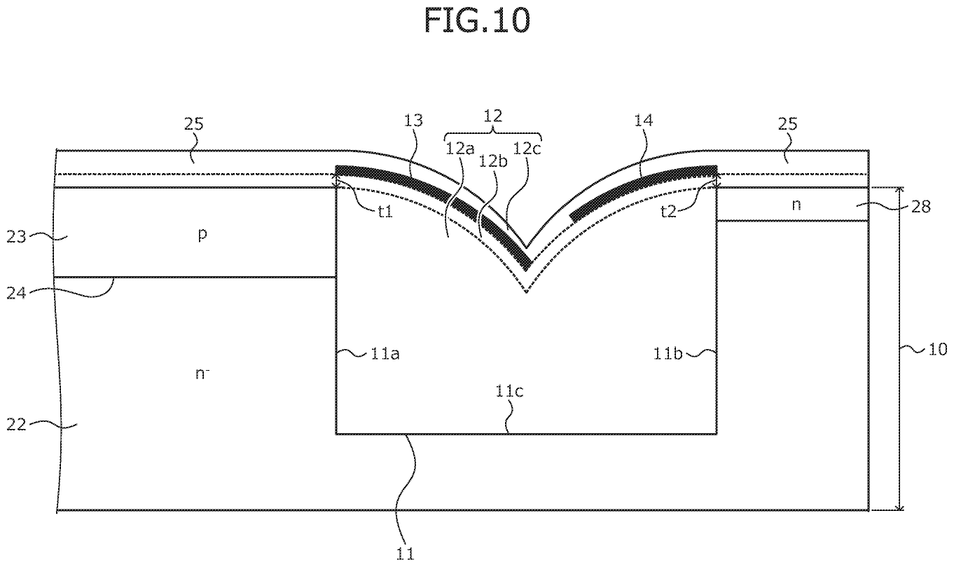

Next, as depicted in FIG. 10, the oxide film (second oxide film) 12c constituting the embedded insulating film 12 is deposited by a CVD method so as to cover the oxide film 12b, the inner FP 13, and the outer FP 14 (seventh process). A portion of the oxide film 12c covering the oxide film 12a constitutes the embedded insulating film 12 while a portion of the oxide film 12c covering the p-type region 23 and the n-type channel stopper region 28 increases a thickness of the interlayer insulating film 25. A surface of the oxide film 12c above the trench 11 has a cross-sectional shape that is substantially identical to that of the surface of the oxide film 12b therebelow.

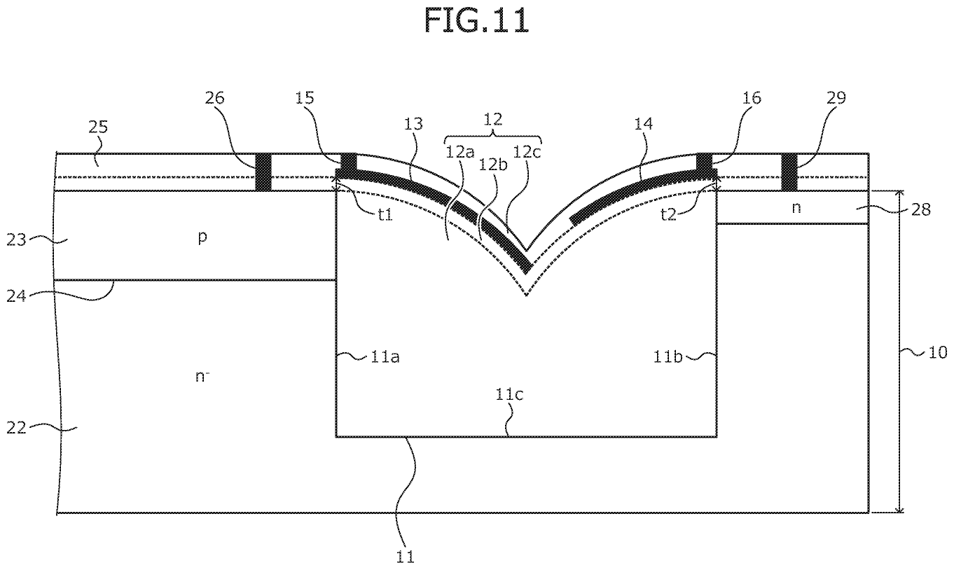

Next, as depicted in FIG. 11, contact holes are formed that penetrate the interlayer insulating film 25 in the depth direction and respectively reach the p-type region 23 and the n-type channel stopper region 28. Further, contact holes are formed that penetrate the oxide film 12c in the depth direction and respectively reach the inner FP 13 and the outer FP 14. Next, in the contact holes that respectively expose the p-type region 23, the n-type channel stopper region 28, the inner FP 13, and the outer FP 14, metal films constituting the first to the fourth contacts 26, 29, 15, and 16, respectively, are embedded.

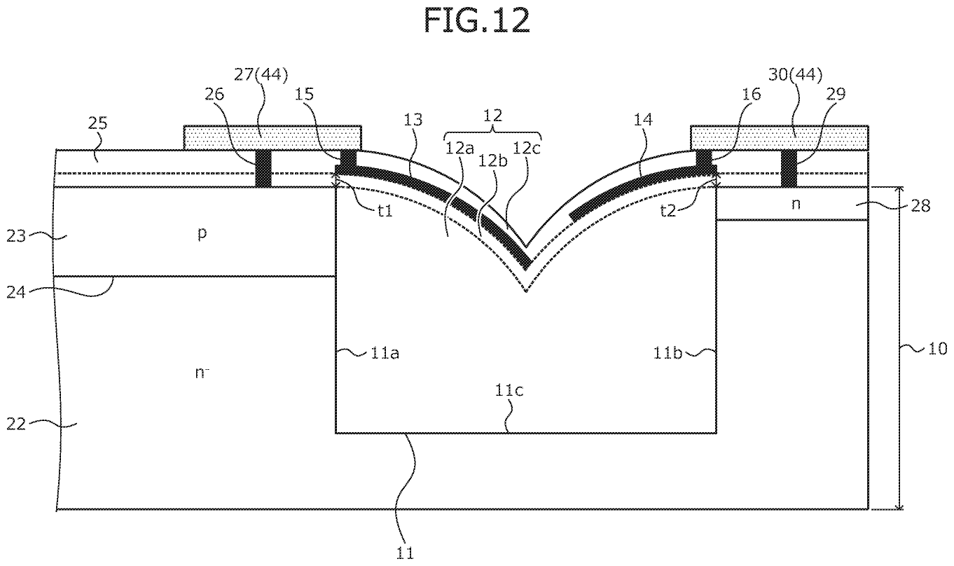

Next, as depicted in FIG. 12, a metal film 44 constituting the first and the second metal wiring layers 27, 30 is deposited on the oxide film 12c so as to cover the first to the fourth contacts 26, 29, 15, and 16. Next, the metal film 44 is patterned, whereby portions of the metal film 44 constituting the first and the second metal wiring layers 27, 30 are left. As a result, the first metal wiring layer 27 that is in contact with the first and the third contacts 26, 15 is formed and the second metal wiring layer 30 that is in contact with the second and the fourth contacts 29, 16 is formed. The first and the second metal wiring layers 27, 30 may be formed concurrently with the source electrode of the MOSFET.

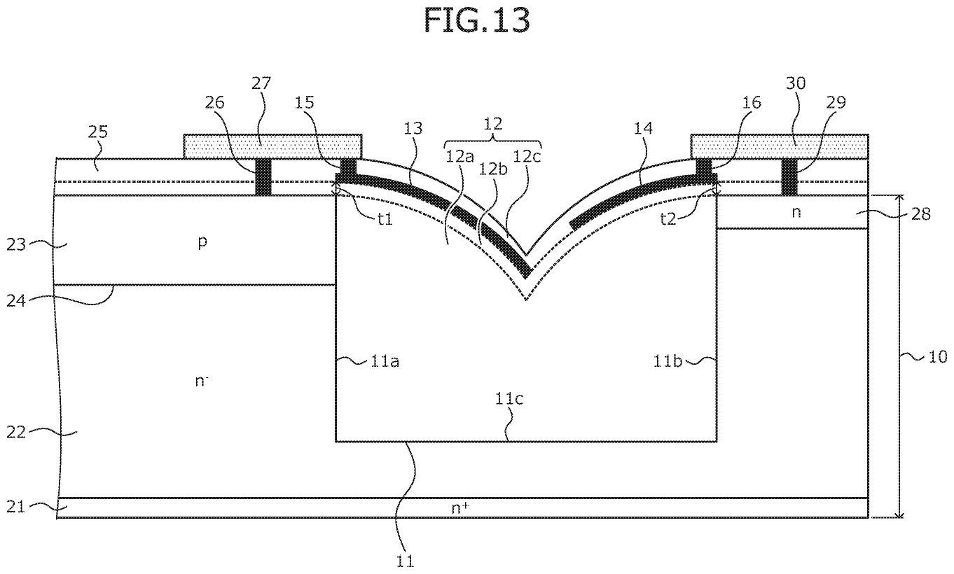

Next, as depicted in FIG. 13, by ion implantation of an n-type impurity, the n⁺-type drain region 21 is formed in the surface layer at the rear surface of the semiconductor substrate 10 so as to span the rear surface of the semiconductor substrate 10 overall. Next, the drain electrode 31 is formed on the rear surface of the semiconductor substrate 10. While not depicted, the MOS gate structure of the active region 1 is suitably formed by a general method, for example, before formation of the interlayer insulating film 25. Thereafter, the semiconductor substrate 10 is cut (diced) into individual chips, whereby the semiconductor device depicted in FIG. 1 is completed.

The semiconductor substrate 10 may be a bulk substrate cut from an ingot, or may be epitaxial substrate in which an n⁻-type semiconductor layer constituting the n⁻-type drift region 22 is formed by epitaxial growth on an n⁺-type starting substrate constituting the n⁺-type drain region 21. The bulk substrate may be manufactured by a float zone (FZ) method, a Czochralski (CZ) method, or a magnetic field applied Czochralski (MCZ) method. When a bulk substrate is used as the semiconductor substrate 10, after the semiconductor substrate 10 is ground from the rear surface to a product thickness, the n⁺-type drain region 21 may be formed by ion implantation, in the surface layer at the rear surface of the semiconductor substrate 10 after grinding.

As described, according to the first embodiment, a termination structure is included in which the trench that has a wide width and is provided in the edge termination region is embedded with the embedded insulating film, and an end of the pn junction between the p-type region of the active region and the n⁻-type drift region is terminated at the embedded insulating film. As the insulating material of the embedded insulating film constituting the termination structure, an oxide film is used that is deposited by, for example, a CVD method. The oxide film has a breakdown field strength that is high as compared to BCB that is used as the insulating material of the embedded insulating film in the conventional structure (refer to FIG. 34). Therefore, the breakdown field strength of the embedded insulating film may be increased as compared to the conventional structure in which BCB is used as the insulating material of the embedded insulating film. As a result, the width of the embedded insulating film may be reduced, thereby enabling the width of the edge termination region in a direction from the center portion of the semiconductor substrate toward the side surface of the semiconductor substrate to be shortened and accordingly, enabling reductions in chip size.

Further, according to the first embodiment, in the embedded insulating film constituting the termination structure, the inner FP is provided toward an inner side wall of the trench, the inner side wall being the wall nearest the active region. The inner FP opposes an inner top corner portion of the trench, across the embedded insulating film, the inner top corner portion being the top corner portion nearest the active region. The inner FP has a protrusion-like shape that protrudes in a direction away from the inner side wall and the bottom of the trench. Due to the inner FP, toward the active region, an equipotential line of substantially 0V distributed along the front surface of the semiconductor substrate is curved so as to be separated from the inner side wall and the bottom of the trench, along the inner FP near the top corner portion of the inner side wall of the trench. As a result, high electric field is applied to a portion that is separated from and further on the active region 1 side than is an inner bottom corner portion of the trench and the concentration of electric field near the inner bottom corner portion of the trench is mitigated, whereby destruction near the inner bottom corner portion of the trench becomes less likely even with breakdown. Therefore, the breakdown capability at the edge termination region is enhanced.

Further, according to the first embodiment, the embedded insulating film constituting the termination structure is formed by embedding the trench with an oxide film deposited by a CVD method. The surface of the oxide film deposited by the CVD method has a recess that is deepest at the center portion of the trench. The surface of the oxide film is formed in a shape of protrusions that respectively protrude upward in a direction away from the side walls of the trench. Therefore, by merely patterning a conductive film deposited along the surface of the oxide film, the inner FP may be formed to have a protrusion-like shape that protrudes in a direction away from the inner side wall and the bottom of the trench.

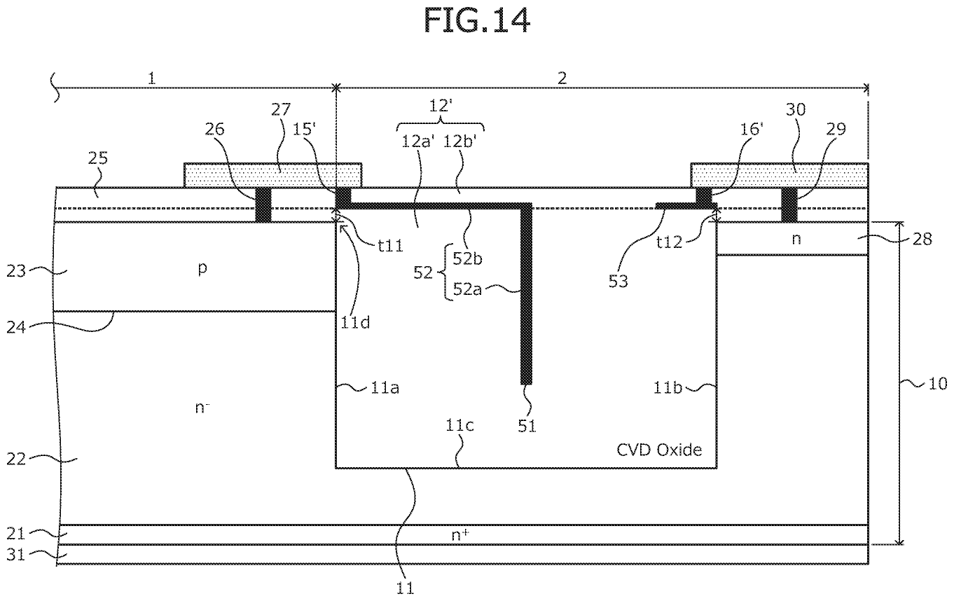

Next, a termination structure of the semiconductor device according to a second embodiment will be described. FIG. 14 is a cross-sectional view of the termination structure of the semiconductor device according to the second embodiment. The semiconductor device according to the second embodiment differs from the semiconductor device according to the first embodiment in that in substantially a center of an embedded insulating film 12′ that is embedded in the trench (hereinafter, silicon trench) 11, an inner FP 52 is embedded that extends in a direction orthogonal to the front surface of the semiconductor substrate 10, toward the drain electrode 31.

In particular, a trench (hereinafter, oxide film trench (groove)) 51 is provided in substantially a center of the embedded insulating film 12′. The oxide film trench 51 has a width that is narrower than that of the silicon trench 11. The oxide film trench 51 protrudes in substantially the center of the embedded insulating film 12′, from the front surface side of the semiconductor substrate 10 toward the drain electrode 31, to have a long linear shape. A surface of the embedded insulating film 12′ is substantially parallel to the front surface of the semiconductor substrate 10.

In FIG. 14, a dashed line in the embedded insulating film 12′ represents a boundary between oxide films (first and second oxide films) 12a′, 12b′ constituting the embedded insulating film 12′ that is deposited in stages (here, 2 stages) in the trench 11, when the inner FP 13 and the outer FP 14 are embedded in the embedded insulating film 12′, as described hereinafter. Surfaces of the oxide films 12a′, 12b′ are both substantially parallel to the front surface of the semiconductor substrate 10.

The inner FP 52 is embedded in the oxide film trench 51 and extends substantially orthogonal to the front surface of the semiconductor substrate 10, in a linear shape from the front surface side of the semiconductor substrate 10 toward the drain electrode 31. Further, the inner FP 52 is positioned to be separated from the front surface of the semiconductor substrate 10 by the predetermined distance t11, by the embedded insulating film 12 or the interlayer insulating film 25 between the inner FP 52 and the front surface of the semiconductor substrate 10. The inner FP 52 extends from substantially the center of the embedded insulating film 12′ toward the active region 1, in a direction (lateral direction) substantially parallel to the front surface of the semiconductor substrate 10 and is connected to the third contact 15.

In particular, the inner FP 52 has a substantially L-shaped cross-sectional shape in which an end of a first linear portion 52a that, in substantially the center of the embedded insulating film 12′, is long and extends along the vertical direction from the front surface side of the semiconductor substrate 10 and toward the drain electrode 31 and an end of a second linear portion 52b that is long and extends in the lateral direction from substantially the center of the embedded insulating film 12′ and toward the active region 1 are connected to each other. In other words, the inner FP 52 has a protrusion-like shape that protrudes in a direction away from the inner side wall 11a and the bottom 11c of the silicon trench 11 and that is formed by a substantially right-angled vertex portion formed by the connected ends of the first and the second linear portions 52a, 52b.

The first linear portion 52a of the inner FP 52 opposes each of the inner and the outer side walls 11a, 11b of the silicon trench 11 over a same distance along the depth direction. An end of the second linear portion 52b of the inner FP 52, the end opposite the one connected to the first linear portion 52a, is connected to the third contact 15′. The end of the second linear portion 52b of the inner FP 52, the one connected to the third contact 15′, opposes the inner top corner portion 11d of the silicon trench 11, across the embedded insulating film 12′ or the interlayer insulating film 25.

An outer FP 53 is positioned to be separated from the front surface of the semiconductor substrate 10 by a predetermined distance t12, by the embedded insulating film 12 or the interlayer insulating film 25 therebetween. Along a direction parallel to the front surface of the semiconductor substrate 10, the outer FP 53 extends outward toward the side surface of the semiconductor substrate 10, from a position closer to the side surface of the semiconductor substrate 10 than is substantially the center of the embedded insulating film 12′. The outer FP 53 is connected to the fourth contact 16′. The outer FP 53, for example, is positioned at a same depth as that of the second linear portion 52b of the inner FP 52. The outer FP 53 is disposed separated from the inner FP 52.

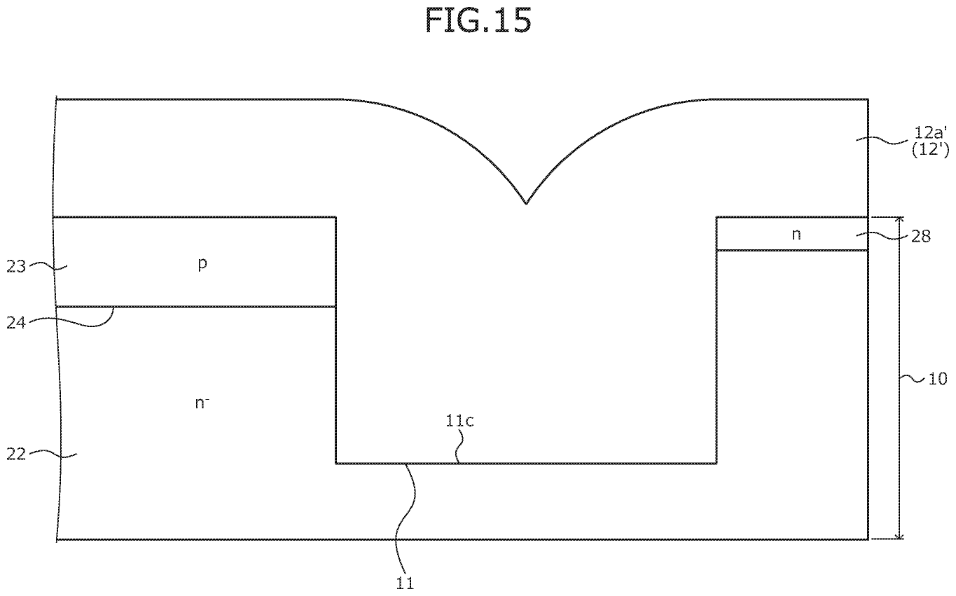

Next, the method of manufacturing the semiconductor device according to the second embodiment will be described with reference to FIGS. 1 to 4, and 15 to 22. FIGS. 15, 16, 17, 18, 19, 20, 21, and 22 are cross-sectional views of the semiconductor device according to the second embodiment during manufacture. First, similarly to the first embodiment, the semiconductor substrate (semiconductor wafer) 10 constituting the n⁻-type drift region 22 is prepared and processes from forming the p-type region 23 to forming the silicon trench 11 are sequentially performed (refer to FIGS. 1 to 4). Next, the silicon nitride film 42 used in forming the silicon trench 11 (refer to FIG. 5) is removed.

Next, as depicted in FIG. 15, the oxide film 12a′ constituting the embedded insulating film 12′ is deposited by a CVD method and the silicon trench 11 is completely embedded with the oxide film 12a′ (third process). Here, the oxide film 12a′ is further deposited on the front surface of the semiconductor substrate 10. Further, at a surface of the oxide film 12a′, a portion recessed toward the bottom 11c of the silicon trench 11 occurs at a portion on the silicon trench 11. Therefore, the oxide film 12a′ is formed to have a thickness so that the recessed portion at the surface of the oxide film 12a′ does not remain after a CMP process of the oxide film 12a′ described hereinafter.

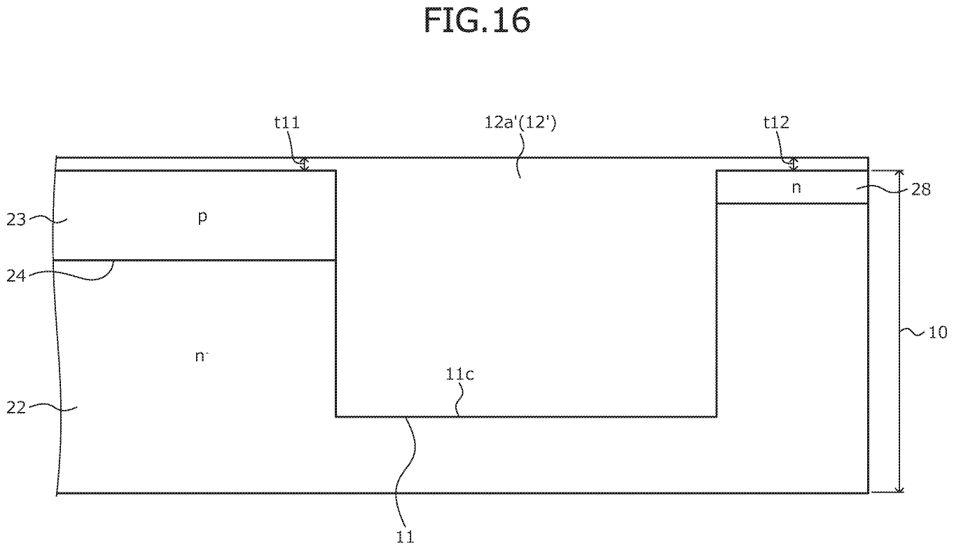

Next, as depicted in FIG. 16, the surface of the oxide film 12a′ is polished by a chemical mechanical polishing (CMP) process and the surface of the oxide film 12a′ is planarized (fourth process). Here, the oxide film 12a′ is also left on the front surface of the semiconductor substrate 10. Thicknesses of the portions of the oxide film 12a′ remaining on the front surface of the semiconductor substrate 10 are respectively set to be equal to the predetermined distances t11, t12 from the second linear portion 52b and the outer FP 53 of the inner FP 52 formed at a subsequent process to the front surface of the semiconductor substrate 10.

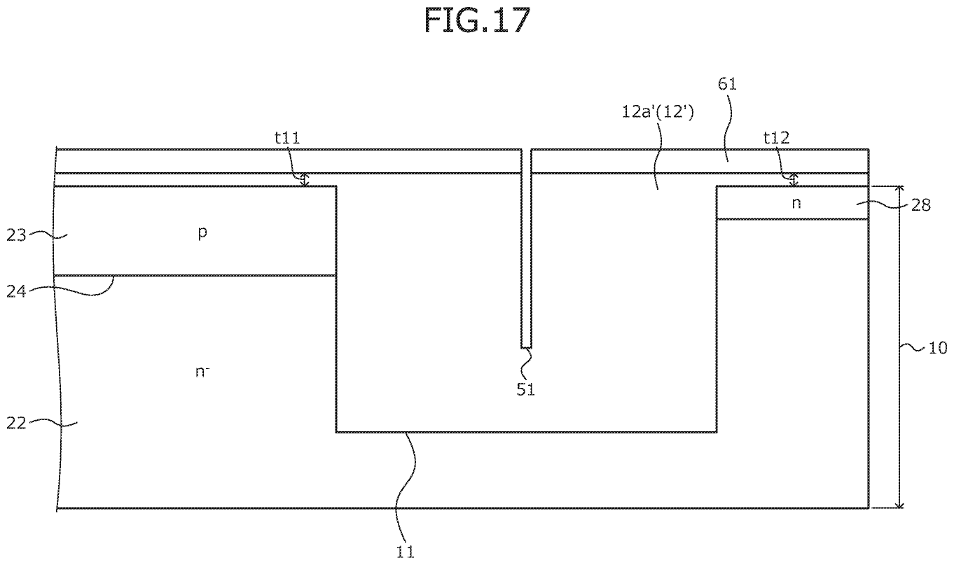

Next, as depicted in FIG. 17, a silicon nitride film 61 is formed on the surface of the oxide film 12a′. Next, the silicon nitride film 61 is selectively removed, exposing a portion of the semiconductor substrate 10 corresponding to a formation region of the oxide film trench 51. Next, portions remaining of the silicon nitride film 61 are used as a mask to thereby form the oxide film trench 51 that reaches a predetermined depth from the front surface of the semiconductor substrate 10 (fifth process). The oxide film trench 51 has side walls substantially orthogonal to the front surface of the semiconductor substrate 10. Next, the remaining portions of the silicon nitride film 61 are removed.

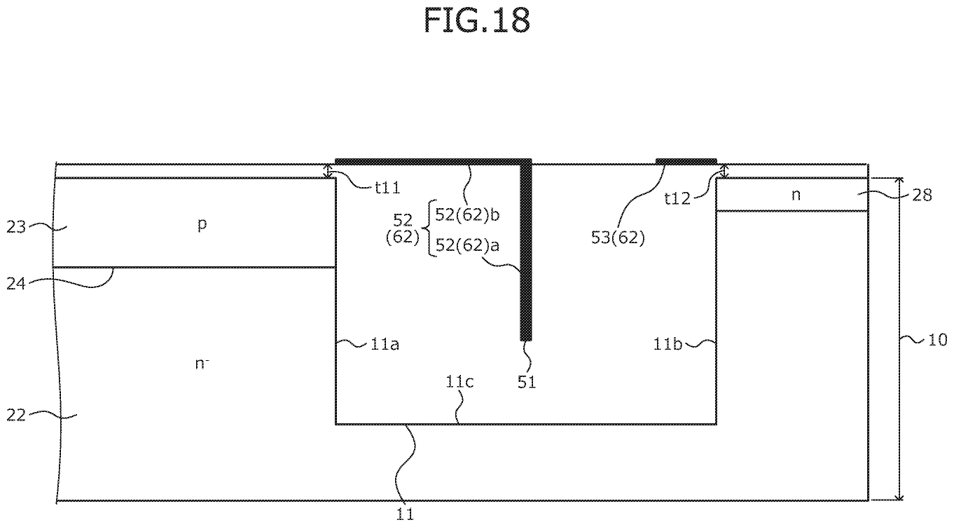

Next, as depicted in FIG. 18, a conductive film 62 is embedded in the oxide film trench 51. Here, the conductive film 62 is further deposited on the surface of the oxide film 12a′ (sixth process). A surface of the conductive film 62 is a flat surface parallel to the surface of the oxide film 12a′. The conductive film 62 is formed by depositing tungsten, via a barrier metal. Alternatively, the conductive film 62 is formed by depositing poly-silicon. Next, the conductive film 62 is patterned so that portions of the conductive film 62 constituting the inner FP 52 and the outer FP 53 remain (seventh process). A portion of the conductive film 62 embedded in the oxide film trench 51 constitutes the first linear portion 52a of the inner FP 52 extending orthogonal to the front surface of the semiconductor substrate 10, toward the drain electrode 31.

The second linear portion 52b of the inner FP 52 and the outer FP 53 are formed separated from each other by portion of the conductive film 62 on the surface of the oxide film 12a′. The second linear portion 52b of the inner FP 52 and the outer FP 53 extend along the surface of the oxide film 12a′ and are orthogonal to the first linear portion 52a of the inner FP 52. Ends of the first and the second linear portions 52a, 52b of the inner FP 52 are connected to each other. The second linear portion 52b of the inner FP 52 and the outer FP 53 are respectively formed at positions separated from the front surface of the semiconductor substrate 10 in an upward direction by the predetermined distances t11, t12 that are equal to the respective thicknesses of the portions of the oxide film 12a′ on the front surface of the semiconductor substrate 10.

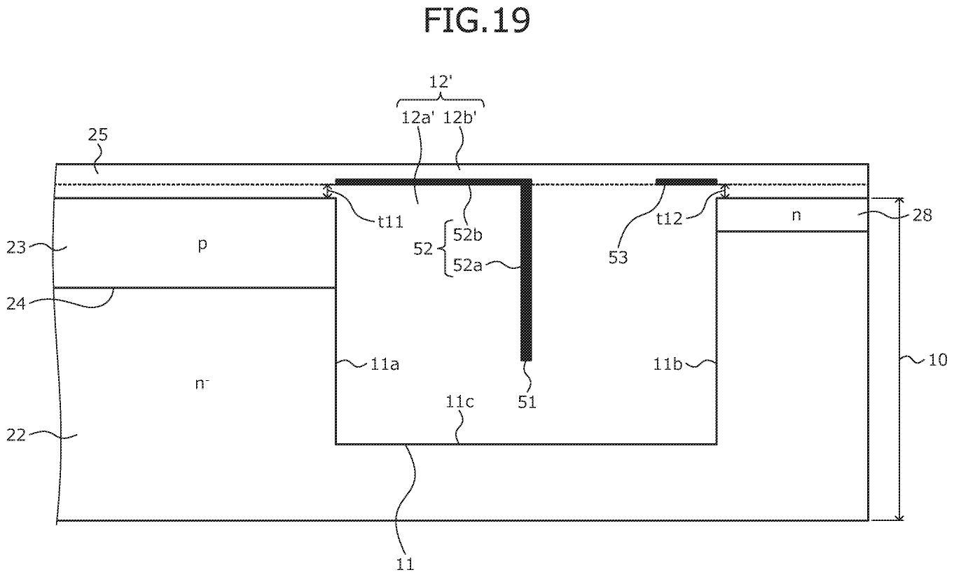

Next, as depicted in FIG. 19, the oxide film 12b′ constituting the embedded insulating film 12′ is deposited on the front surface of the semiconductor substrate 10 and the oxide film 12a′ by a CVD method so as to cover the oxide film 12a′, the inner FP 52, and the outer FP 53 (eighth process). A portion of the oxide film 12b′ on the silicon trench 11 constitutes the embedded insulating film 12′ covering the inner FP 52 and the outer FP 53, while portions covering the p-type region 23 and the n-type channel stopper region 28, across the oxide film 12a′ constitute the interlayer insulating film 25. A surface of the oxide film 12b′ is a flat surface that is parallel to the surface of the oxide film 12a′ below.

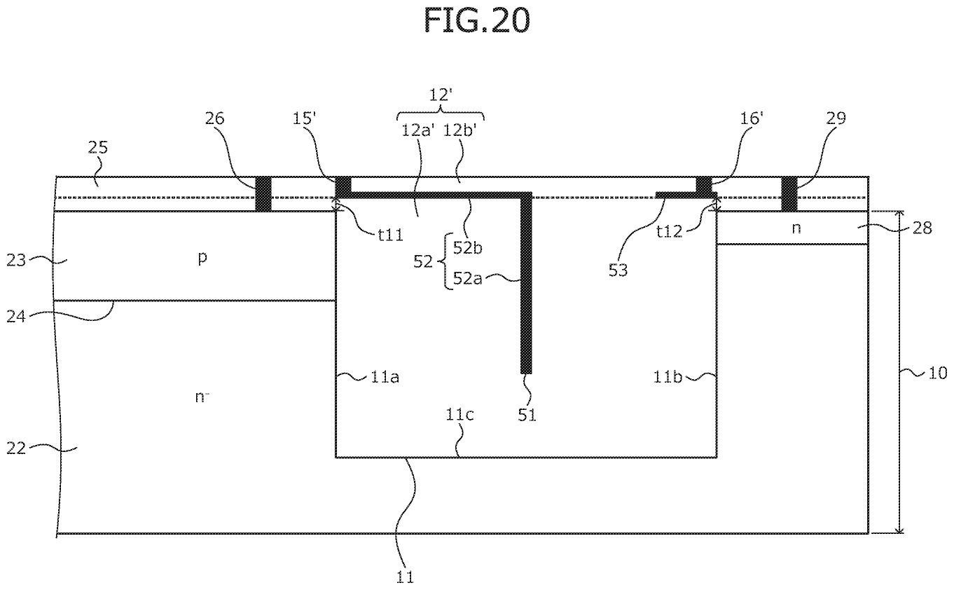

Next, as depicted in FIG. 20, contact holes are formed to penetrate the interlayer insulating film 25 in the depth direction, and reach the p-type region 23 and the n-type channel stopper region 28, respectively. Further, contact holes are formed to penetrate the oxide film 12b′ in the depth direction, and reach the inner FP 52 and the outer FP 53, respectively. Next, in the contact holes respectively exposing the p-type region 23, the n-type channel stopper region 28, the inner FP 52 and the outer FP 53, metal films constituting the first to the fourth contacts 26, 29, 15′, 16′ are embedded, respectively.

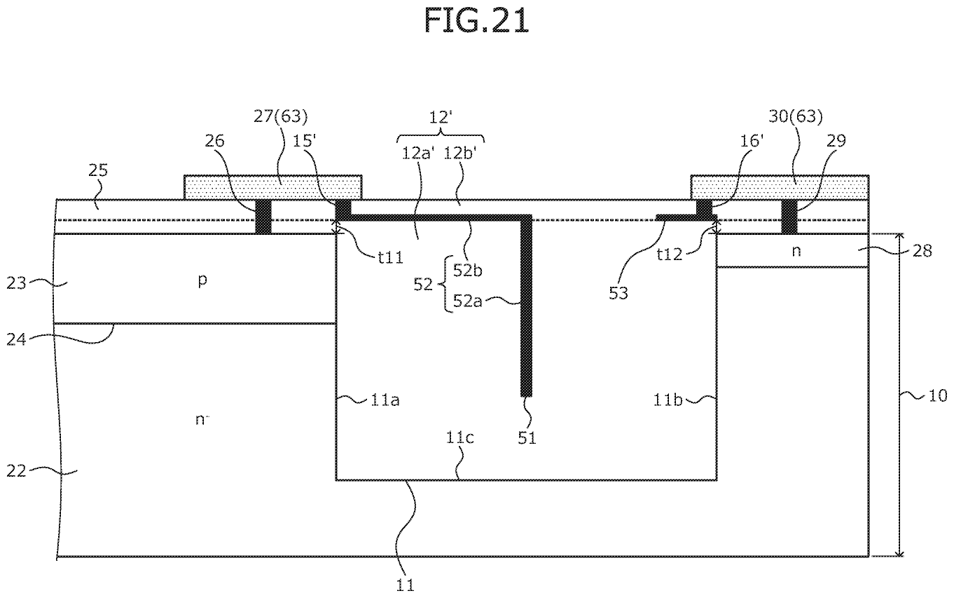

Next, as depicted in FIG. 21, a metal film 63 that constitutes the first and the second metal wiring layers 27, 30 is deposited on the oxide film 12b′ so as to cover the first to the fourth contacts 26, 29, 15′, 16′. Next, the metal film 63 is patterned so that portions of the metal film 63 respectively constituting the first and the second metal wiring layers 27, 30 remain. As a result, the first metal wiring layer 27 that is in contact with the first and the third contacts 26, 15′ is formed, and the second metal wiring layer 30 that is in contact with the second and the fourth contacts 29, 16′ is formed. The first and the second metal wiring layers 27, 30 may be formed concurrently with the source electrode of the MOSFET.

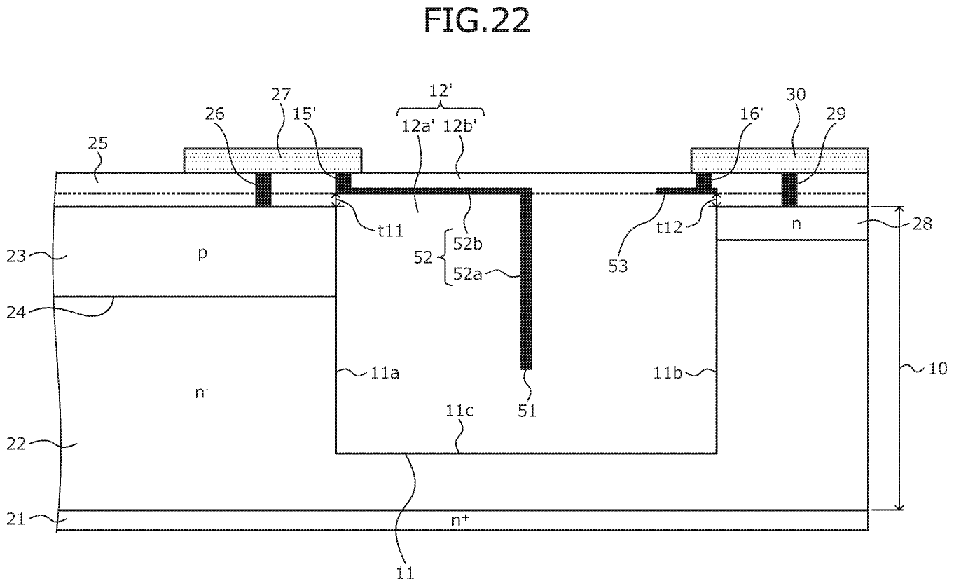

Next, as depicted in FIG. 22, by ion implantation of an n-type impurity, the n⁺-type drain region 21 is formed in the surface layer at the rear surface of the semiconductor substrate 10 so as to span the rear surface of the semiconductor substrate 10 overall. Next, the drain electrode 31 is formed on the rear surface of the semiconductor substrate 10. While not depicted, the MOS gate structure of the active region 1 is suitably formed by a general method, for example, before the formation of the interlayer insulating film 25. Thereafter, the semiconductor substrate 10 is cut (diced) into individual chips, whereby the semiconductor device depicted in FIG. 14 is completed.

As described above, according to the second embodiment, even when the inner FP has a substantially L-shape, a protrusion-like shape that protrudes in a direction away from the inner side wall and the bottom of the trench is formed, thereby enabling effects similar to those of the first embodiment to be obtained. Further, according to the second embodiment, the inner FP is formed by the conductive film embedded in the oxide film trench and the inner FP is long and extends in a direction orthogonal to the front surface of the semiconductor substrate, toward the drain electrode, thereby enabling the concentration of electric field near the inner bottom corner portion of the trench to be further mitigated.

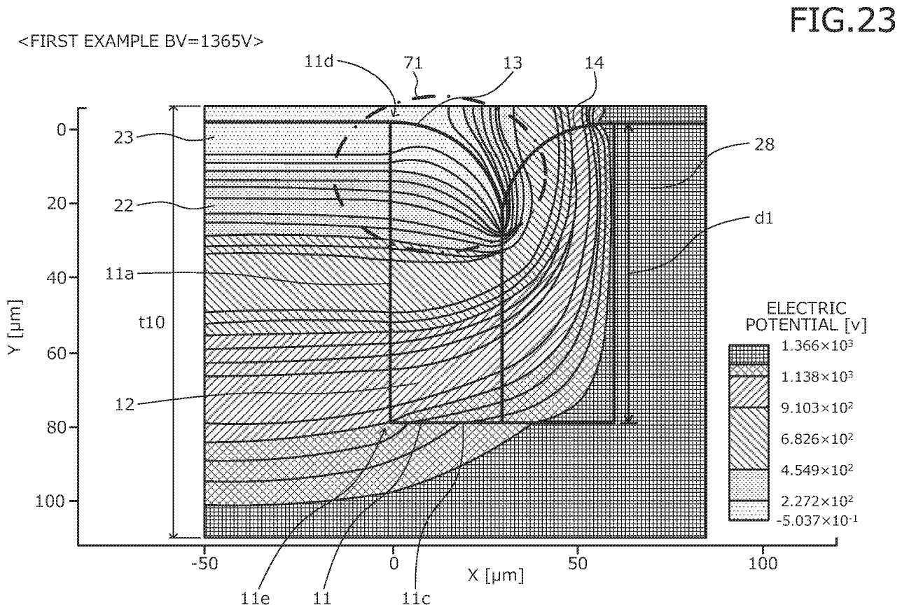

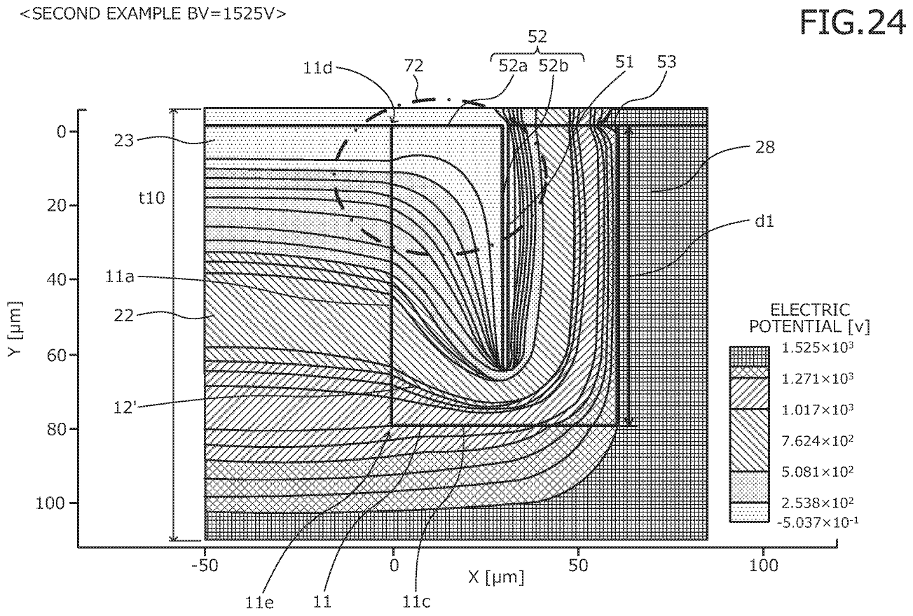

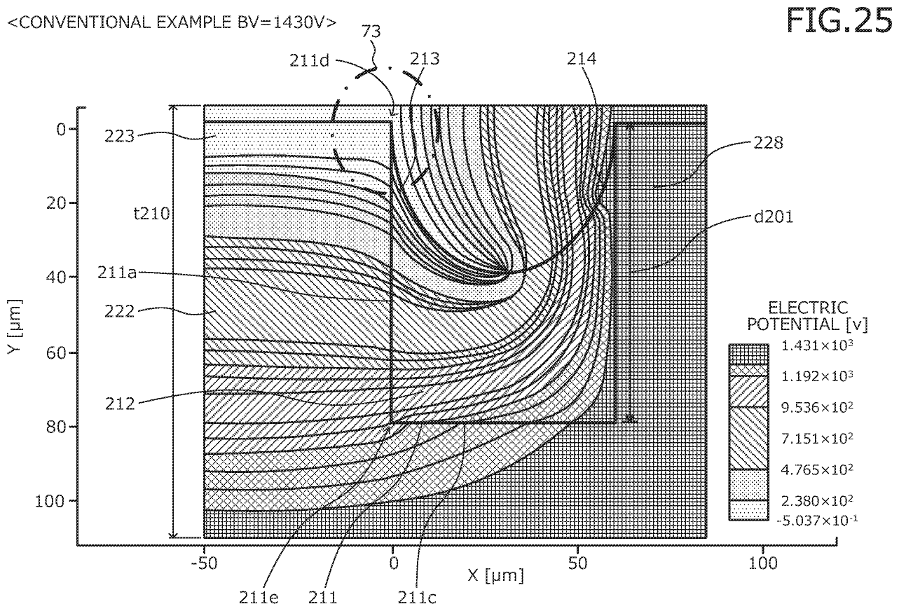

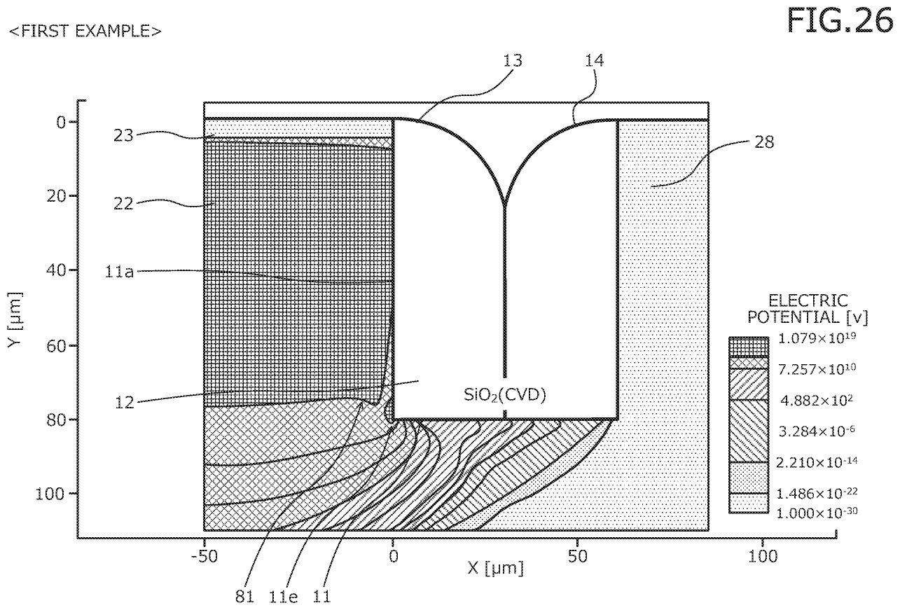

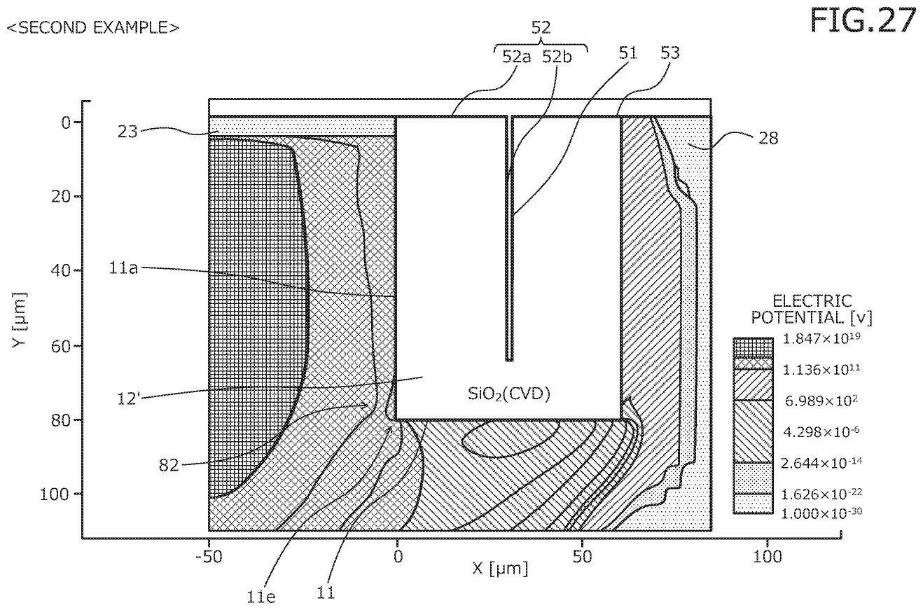

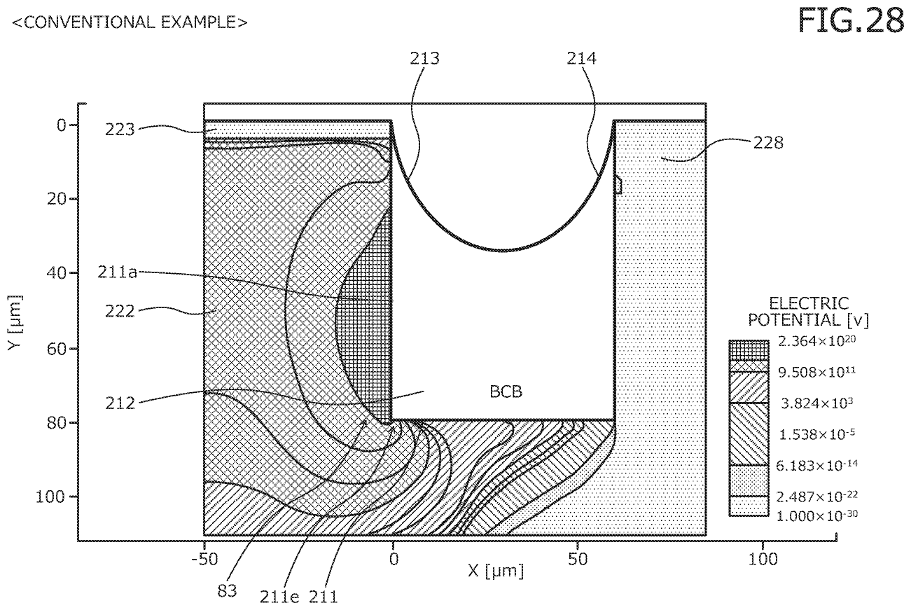

Breakdown voltage of the edge termination region 2 of the semiconductor device according to the first and the second embodiments above was verified. In particular, a relationship of breakdown voltage (BV) when reverse voltage is applied to the pn junction 24, the location of where electric field concentrates in the edge termination region 2, and breakdown voltage of the edge termination region 2 was verified. FIGS. 23 and 24 are diagrams depicting equipotential line distribution of an edge termination region of first and second examples, respectively. FIG. 25 is a diagram depicting equipotential line distribution of an edge termination region of a conventional example. FIGS. 26 and 27 are diagrams depicting electric field distribution of the edge termination region of the first and the second examples, respectively. FIG. 28 is diagram depicting electric field distribution of an edge termination region of a conventional example.

In FIGS. 23, 24, 26, and 27, a horizontal axis is a distance X [μm] from the inner side wall 11 a of the silicon trench 11 (X=0 μm) in the lateral direction. A negative side of the distance X is on the inner side (the active region 1 side) of the semiconductor substrate 10 and a positive side of the distance X is on an outer side (the side surface side of the semiconductor substrate 10) of the semiconductor substrate 10. In FIGS. 23, 24, 26, and 27, a vertical axis is a depth Y [μm] from the front surface (Y=0 μm) of the semiconductor substrate 10. In FIGS. 25 and 28, a horizontal axis is the distance X [μm] from the side wall 211a (X=0 μm) of the trench 211 along the lateral direction. The negative side of the distance X is on the inner side (the active region 201 side) of the semiconductor substrate 210 and the positive side thereof is on the outer side (the side surface side of the semiconductor substrate 210) of the semiconductor substrate 210. In FIGS. 25 and 28, a vertical axis is the depth Y [μm] from the front surface (Y=0 μm) of the semiconductor substrate 210.

First, as the termination structures of the semiconductor devices (refer to FIGS. 1 and 14) according to the first and the second embodiments above, MOSFETs respectively having the embedded insulating films 12, 12′ constituted by silicon oxide films were fabricated (hereinafter, the first and the second examples). In the first and the second examples, resistivity of the semiconductor substrate 10 of an n⁻-type and constituting the n⁻-type drift region 22 was set to 500/cm and a thickness t10 was set to 110 μm. A depth dl of the silicon trench 11 was set to 80 μm. An impurity concentration of the p-type region 23 was set with respect to an impurity concentration of the n⁻-type drift region 22 so that the breakdown voltage of the diode formed at the pn junction 24 between the p-type region 23 and the n⁻-type drift region 22 was 1392V. The equipotential line distribution of the edge termination regions 2 of the first and the second examples are respectively depicted in FIGS. 23 and 24, while the electric field distribution is depicted in FIGS. 26 and 27.

For comparison, as the termination structure of the conventional semiconductor device (refer to FIG. 34), the MOSFET having the embedded insulating film 212 constituted by BCB was fabricated (hereinafter, conventional example). In the conventional example, resistivity of the semiconductor substrate 210 of an n⁻-type and constituting the n⁻-type drift region 222, a thickness t210 of the semiconductor substrate 210, a depth d201 of the trench 211 were similar to those in the first example. An impurity concentration of the p-type region 223 was set with respect to an impurity concentration of the n⁻-type drift region 222 so that voltage of a diode formed at the pn junction 224 between the p-type region 223 and the n⁻-type drift region 222 was 1392V, similarly to the first example. Equipotential line distribution of the edge termination region 202 of the conventional example is depicted in FIG. 25 while electric field distribution is depicted in FIG. 28.

As depicted in FIG. 25, in the conventional example, on the active region 201 side, an equipotential line of substantially 0V distributed along the front surface of the semiconductor substrate 210 is curved in a protrusion-like shape protruding so as to approach the side wall 211a and the bottom 211c of the trench 211 (lower right in FIG. 25), along the inner FP 213 in a vicinity 73 of an inner top corner portion 211d of the trench 211. As a result, as depicted in FIG. 28, in a vicinity 83 of the side wall 211a of the trench 211, electric field concentrates at a silicon portion (the n⁻-type drift region 222) and in particular, the electric field is high at a silicon portion near an inner bottom corner portion 211e of the trench 211. While the breakdown voltage of the pn junction 224 of the conventional example was 1430V, destruction easily occurred at the site of electric field concentration of the silicon portion and the breakdown voltage of the edge termination region 202 was confirmed to decrease. The inner bottom corner portion 211e of the trench 211 is a boundary between the side wall 211a and the bottom 211c of the trench 211.

Meanwhile, as depicted in FIGS. 23 and 24, in the first and the second examples, on the active region 1 side, an equipotential line of substantially 0V distributed along the front surface of the semiconductor substrate 10 is curved so as to be separated from the inner side wall 11 a and the bottom 11c of the silicon trench 11, along the inner FP 13 in vicinities 71, 72 of the inner top corner portion 11d of the silicon trench 11 (upper right in FIGS. 23 and 24). As a result, as depicted in FIG. 26, in the first example, in a region further on the inner side of the semiconductor substrate 10 than is the silicon trench 11, electric field is applied uniformly to the front surface side of the semiconductor substrate 10 overall, and electric field concentration in a vicinity 81 of an inner bottom corner portion 11e of the silicon trench 11 was confirmed to decrease. Further, in the second example, as depicted in FIG. 27, in the semiconductor substrate 10, the electric field is highest at a portion separated from the inner side wall 11a of the silicon trench 11 in a direction toward the active region 1, and electric field concentration at a vicinity 82 of the inner bottom corner portion 11e of the silicon trench 11 was confirmed to decrease.

In other words, in the first example, in the semiconductor substrate 10, the electric field is highest at a position closer to the front surface of the semiconductor substrate 10 than is the inner bottom corner portion 11e of the silicon trench 11. The inner bottom corner portion 11e of the silicon trench 11 is a boundary that is a lower end of the inner side wall 11a of the silicon trench 11 and that is between the inner side wall 11a of the silicon trench 11 and the bottom 11c. In the second example, in the semiconductor substrate 10, the electric field is highest at a position that is separated from the inner side wall 11a of the silicon trench 11 in a direction toward the active region 1 of the semiconductor substrate 10. As a result, even in a case of breakdown, destruction at the vicinities 81, 82 of the inner bottom corner portion 11e of the silicon trench 11 is less likely to occur. For example, while the breakdown voltage of the pn junction 24 in the first example was 1365V, destruction at the vicinity 81 of the inner bottom corner portion 11e of the silicon trench 11 was confirmed to be difficult as compared to the conventional example.

Further, it was confirmed that the breakdown voltage of the pn junction 24 was enhanced the deeper that the inner FP extended toward the drain electrode 31. For example, in the second example in which the inner FP 52 is easily extended deeply toward the drain electrode 31, the breakdown voltage of the pn junction 24 could be set to 1525V.

A structure of the semiconductor device according to a third embodiment will be described. The semiconductor device according to the third embodiment differs from the semiconductor device according to the second embodiment in that breakdown voltage (hereinafter, deep trench isolation (DTI) edge breakdown voltage) during breakdown at the inner bottom corner portion 11e of the silicon trench 11 obtained by the embedded insulating film 12 was set to be equal to or higher than breakdown voltage (hereinafter, planar breakdown voltage) during breakdown obtained at the pn junction 24 between the p-type region 23 and the n⁻-type drift region 22.

In particular, resistivity of the n⁻-type drift region 22 was adjusted to be lower (i.e., the impurity concentration of the n⁻-type drift region 22 was adjusted to be higher), whereby the DTI edge breakdown voltage could be set to be the planar breakdown voltage or higher. Therefore, the resistivity of the n⁻-type drift region 22 whereby the DTI edge breakdown voltage is the planar breakdown voltage or higher is obtained in advance and the semiconductor substrate 10 having the obtained resistivity is used to fabricate (manufacture) the semiconductor device according to the third embodiment. Further, with consideration of manufacturing process variation, the DTI edge breakdown voltage may be set to be higher than the planar breakdown voltage.

The third embodiment is applicable to the first embodiment and in the semiconductor device according to the first embodiment, the DTI edge breakdown voltage may be set to be higher than the planar breakdown voltage.

As described, according to the third embodiment, effects similar to those of the first and the second embodiments may be obtained. Further, according to the third embodiment, the DTI edge breakdown voltage is set to be higher than the planar breakdown voltage, thereby enabling destruction at the inner bottom corner portion of the silicon trench constituting the termination structure to be prevented. In other words, the overall breakdown voltage of the semiconductor device is determined by the breakdown voltage of the portion that is further on the inner side of the semiconductor substrate 10 than is than is the silicon trench. Further, according to the third embodiment, even in a semiconductor device in which the resistivity of the n⁻-type drift region is reduced, breakdown may be caused to occur at a silicon portion further on the inner side of the semiconductor substrate than is the silicon trench.

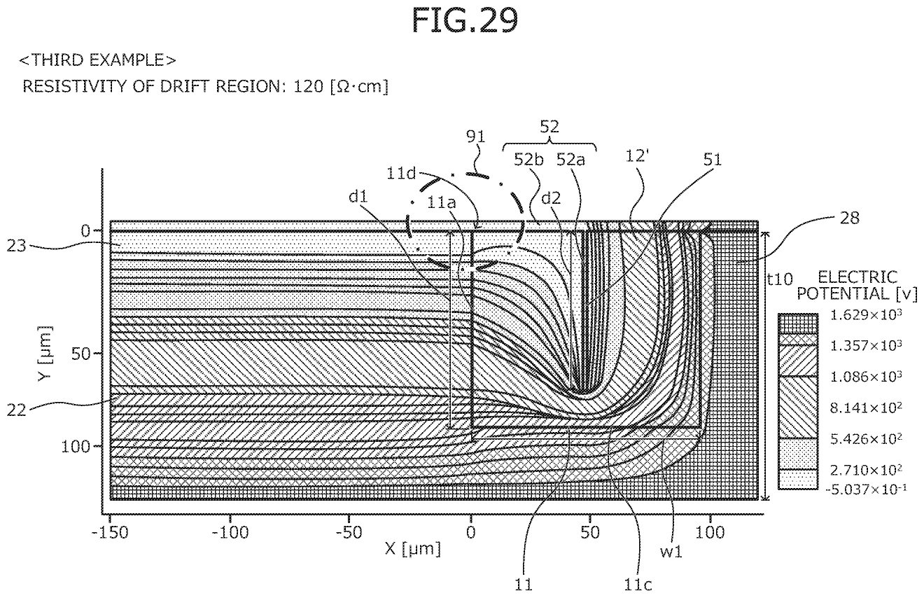

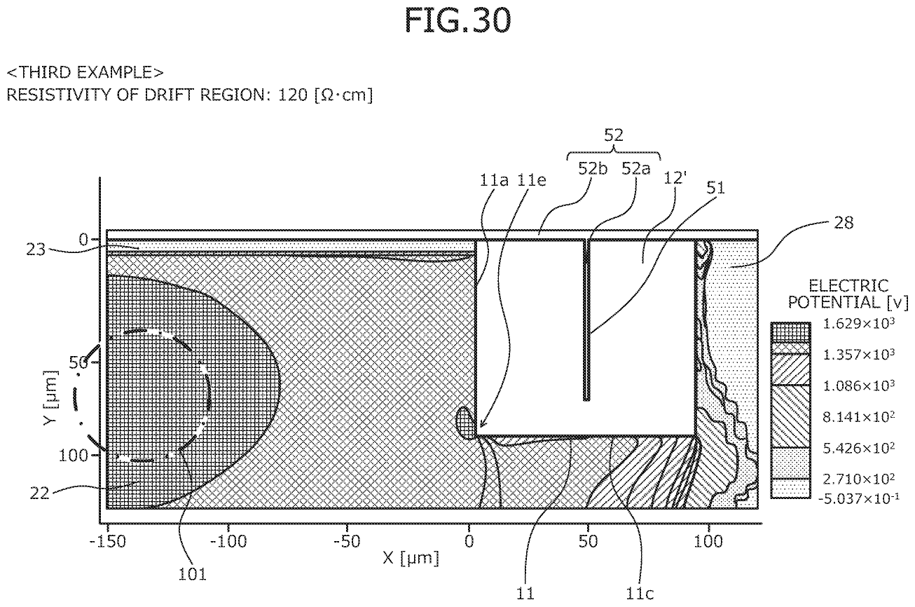

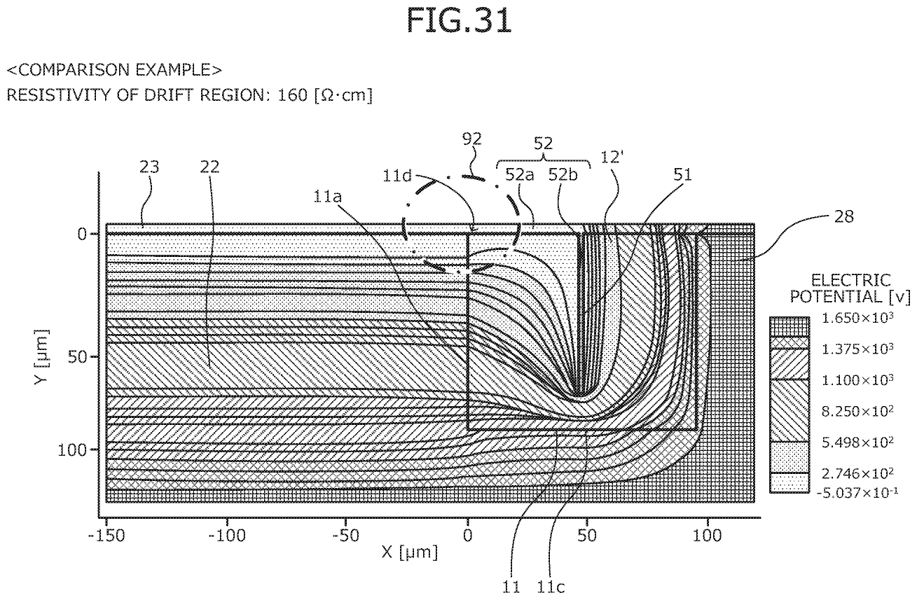

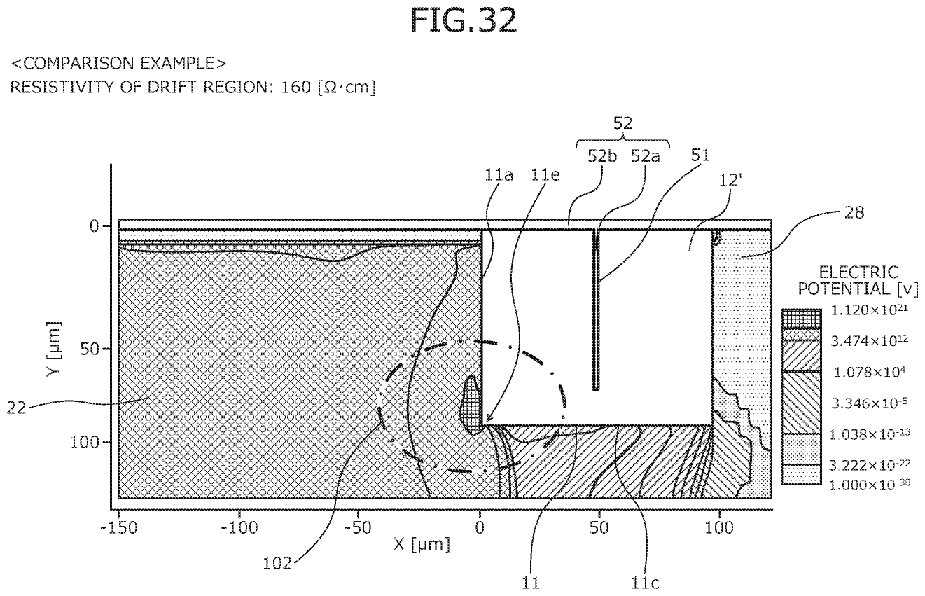

Resistivity of the n⁻-type drift region 22 of the semiconductor device according to the third embodiment was verified. FIG. 29 is a diagram depicting equipotential line distribution of the edge termination region in a third example. FIG. 30 is a diagram depicting electric field distribution of the edge termination region in the third example. FIG. 31 is a diagram depicting equipotential line distribution of an edge termination region in a comparison example. FIG. 32 is a diagram of electric field distribution of the edge termination region in the comparison example.

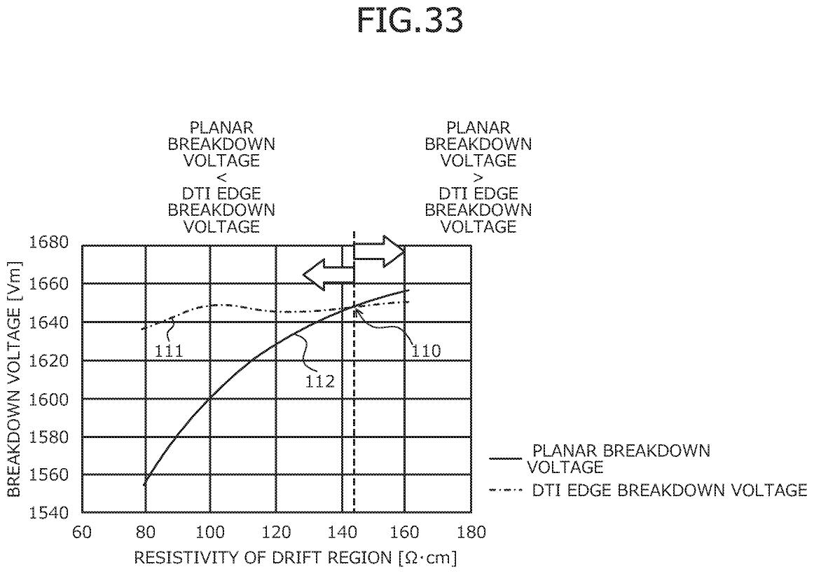

In FIGS. 29 to 32, a horizontal axis is the distance X [μm] from the inner side wall 11a of the silicon trench 11 (X=0 μm) in the lateral direction. The negative side of the distance X is on the inner side of the semiconductor substrate 10 and the positive side thereof is on the outer side of the semiconductor substrate 10. In FIGS. 29 to 32, a vertical axis is the depth Y [μm] from the front surface of the semiconductor substrate 10 (Y=0 μm). FIG. 33 is a diagram depicting a relationship of resistivity of a drift region and breakdown voltage.

First, a MOSFET that includes the termination structure of the described semiconductor device according to the third embodiment (refer to FIG. 14) was fabricated (hereinafter, third example). In the third example, resistivity of the n⁻-type drift region 22 was set to be 120 Ω·cm. Other than the resistivity of the n⁻-type drift region 22, configuration of the third example was similar to that of the second example. Equipotential line distribution of the edge termination region 2 and electric field distribution of the third example are depicted in FIGS. 29 and 30, respectively.

For comparison, a MOSFET that includes a termination structure similar to that of the third example and in which the resistivity of the n⁻-type drift region 22 was set to be higher than that of the third example was fabricated (hereinafter, comparison example). In the comparison example, the resistivity of the n⁻-type drift region 22 was set to be 160 Ω·cm. Other than the resistivity of the n⁻-type drift region 22, configuration of the comparison example was similar to that of the third example. Equipotential line distribution of the edge termination region 2 and electric field distribution of the comparison example are depicted in FIGS. 31 and 32, respectively.

As depicted in FIGS. 29 and 31, the third example and the comparison example were confirmed to have equipotential line distribution similar to that of the second example. In other words, on the active region 1 side, an equipotential line of substantially 0V distributed along the front surface of the semiconductor substrate 10 is curved so as to be separated from the inner side wall 11a and the bottom 11c of the silicon trench 11, along the inner FP 13 in vicinities 91, 92 of the inner top corner portion 11d of the silicon trench 11 (upper right in FIGS. 29 and 31).

On the other hand, as depicted in FIGS. 30 and 32, portions 101, 102 where the electric field is highest in the third example and the comparison example had differing electric field distribution, In particular, in the comparison example, during breakdown, the electric field was highest at the vicinity 102 of the inner bottom corner portion 11e of the silicon trench 11, leading to destruction. In the third example, during breakdown, the electric field was highest at the portion 101 that was further on the inner side of the semiconductor substrate 10 than was the inner side wall 11a of the silicon trench 11, leading to destruction.

A reason for the electric field during breakdown being highest at the portion 101 that was further on the inner side than was the inner side wall 11a of the silicon trench 11, like in the third example, is as follows. As depicted in FIG. 33, while the DTI edge breakdown voltage decreases slightly with the decrease in the resistivity of the n⁻-type drift region 22, the DTI edge breakdown voltage is substantially constant and independent of the resistivity of the n⁻-type drift region 22. On the other hand, the planar breakdown voltage increases as the resistivity of the n⁻-type drift region 22 increases.

In other words, a substantially horizontal curve 111 representing the DTI edge breakdown voltage, which is independent of the resistivity of the n⁻-type drift region 22 and a curve 112 protruding upward and toward the right and representing the planar breakdown voltage that increases dependent on a magnitude of the resistivity of the n⁻-type drift region 22 intersect each other at a single predetermined intersection point 110. The semiconductor substrate 10 of an n⁻-type and having resistivity equal to or less than the resistivity (in FIG. 33, about 140 Ωcm or less) at the intersection point 110 is used, thereby enabling the DTI edge breakdown voltage to be set to be the planar breakdown voltage at most.

In particular, for example, in the third example, the thickness t10 of the semiconductor substrate 10 is assumed to be 110 μm, the depth d1 and a width w1 of the silicon trench 11 are assumed to be 80 μm and 60 μm, a depth d2 of the first linear portion 52a of the inner FP 52 is assumed to be 50 μm (regarding the depths d1, d2 and the width w1, refer to FIG. 29). In this case, an optimal structure of a 1200V semiconductor device suffices to have a resistivity of 145 Ω·cm or less for the semiconductor substrate 10.

In the foregoing, various modifications within a range not departing from the spirit of the invention are possible. For example, in the embodiments, dimensions, impurity concentrations, etc. of parts may be variously set according to required specifications. Further, in the embodiments, while a MOSFET is described as an example, application is further possible to a diode, an insulated gate bipolar transistor (IGBT), etc. In a case of an IGBT, in the surface layer of the rear surface of the n⁻-type semiconductor substrate constituting the n⁻-type drift region, a p⁺-type contact region is formed instead of the n⁺-type drain region.

Further, the n⁻-type semiconductor substrate constituting the n⁻-type drift region may be a bulk wafer cut from an ingot. The bulk wafer may be manufactured by a float zone (FZ) method, a Czochralski (CZ) method, or a magnetic field applied Czochralski (MCZ) method. The n⁻-type semiconductor substrate constituting the n⁻-type drift region may be a bulk wafer that, for example, has been made thinner by grinding the rear surface. Further, the semiconductor substrate may be an epitaxial substrate in which an n⁻-type epitaxial layer constituting the n⁻-type drift region is formed by epitaxial growth on an n⁺-type starting substrate that constitutes the n⁺-type drain region.

In the embodiments above, other than silicon, germanium, or the like, the semiconductor substrate may be a wide bandgap semiconductor substrate containing silicon carbide (SiC), gallium nitride (GaN), diamond, or the like. The present invention is similarly implemented when conductivity types (n-type, p-type) are reversed.

According to the embodiments of the invention, an oxide film is used as an insulating material of the insulating film embedded in the trench constituting the termination structure and provided closer to the side surface of the semiconductor substrate than is the active region. As a result, the breakdown field strength of the insulating film may set higher and the width of the trench constituting the termination structure set narrower as compared to the conventional structure that uses BCB as an insulating material of the insulating film embedded in the trench constituting the termination structure.

According to the embodiments of the invention, on the active region side, an equipotential line of substantially 0V and distributed along the front surface of the semiconductor substrate is curved so as to be separated from the inner side wall and the bottom of the trench, along the field plate near the upper end of the inner side wall of the trench. As a result, the concentration of electric field near the inner bottom corner portion of the trench is mitigated and even with breakdown, destruction near the inner bottom corner portion of the trench becomes less likely to occur.

The semiconductor device and the method of manufacturing a semiconductor device according to the embodiments of the invention achieve an effect in that a reduction in chip size and enhanced breakdown capability are possible.

As described, the semiconductor device and the method of manufacturing a semiconductor device according to the embodiments of the invention are useful for various semiconductor devices in which a termination structure is disposed in the edge termination region.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device having an active region therein, comprising:
a semiconductor substrate having a first main surface and a second main surface opposite to the first main surface, the semiconductor substrate including a first-conductivity-type region and a second-conductivity-type region that is disposed closer to the first main surface than is the first-conductivity-type region;
a trench provided at a position closer to an outer periphery of the semiconductor substrate than is a position of the active region and reaching a predetermined depth from the first main surface of the semiconductor substrate, a pn junction between the first-conductivity-type region and the second-conductivity-type region extending from the active region toward the outer periphery of the semiconductor substrate and being terminated at the trench;
a first insulating film embedded in the trench;
a second insulating film provided on the second-conductivity-type region;
a field plate extending along a depth direction in the first insulating film in the trench;
a first electrode electrically connected to the second-conductivity-type region and the field plate; and
a second electrode provided on the second main surface of the semiconductor substrate, wherein
the field plate has a first end at a position facing an upper end of an inner side wall of the trench and a second end at a position inside the first insulating film, the field plate extending from the inside the first insulating film toward the first main surface of the semiconductor substrate in the active region, and having a protrusion-like shape that protrudes in a direction away from the inner side wall and a bottom of the trench.

2. The semiconductor device according to claim 1, wherein the field plate has a curved portion forming the protrusion-like shape that protrudes in the direction away from the inner side wall and the bottom of the trench.

3. The semiconductor device according to claim 1, wherein
the field plate has a first linear portion and a second linear portion, the first and second linear portions connecting to each other to form a right-angle at a connecting point of the first and second linear portions, and forming a substantially L-shape that protrudes in the direction away from the inner side wall and the bottom of the trench,
the first linear portion extends in the first insulating film in the trench in the depth direction that is orthogonal to the first main surface of the semiconductor substrate,
the second linear portion is provided at a position closer to the first main surface of the semiconductor substrate than is a position of the first linear portion, and extends in a direction parallel to the first main surface of the semiconductor substrate toward the active region.

4. The semiconductor device according to claim 1, wherein a breakdown voltage during breakdown at a lower end of the inner side wall of the trench is higher than a breakdown voltage during the breakdown at the pn junction.

5. The semiconductor device according to claim 1, wherein the first-conductivity-type region has a resistivity of 145 Ω·cm or less.

6. The semiconductor device according to claim 1, wherein each of the first insulating film and the second insulating film is a silicon oxide film.

7. A method of manufacturing a semiconductor device having an active region therein, the method comprising:
forming a semiconductor substrate including a first-conductivity-type region and a second-conductivity-type region on the first-conductivity-type region, to form a pn junction between the first-conductivity-type region and the second-conductivity-type region, the pn junction extending toward an outer periphery of the device from the active region;
forming a trench at a position closer to the outer periphery of the device than is a positon of the active region, to reach a predetermined depth from the first main surface of the semiconductor substrate and terminate the pn junction;
depositing a first oxide film on the first main surface of the semiconductor substrate by a chemical vapor deposition method to embed the first oxide film in the trench;
etching the first oxide film to leave the first oxide film of a predetermined thickness on the first main surface of the semiconductor substrate, and the first oxide film in the trench;
forming a conductive film along a surface of the first oxide film;
selectively removing the conductive film to leave a portion thereof toward the active region as a field plate; and
embedding a second oxide film in the trench to cover the field plate by the second oxide film.

8. The method according to claim 7, wherein the field plate has a first end at a position facing an upper end of an inner side wall of the trench and a second end at a position inside the first oxide film, the field plate having a protrusion-like shape that protrudes in a direction away from the inner side wall and a bottom of the trench.

9. The method according to claim 7, wherein
the semiconductor substrate is of a first conductivity type and has a resistivity that is at most 145 Ω·cm, and
forming the pn junction includes forming the second-conductivity-type region in a surface layer of the first-conductivity-type region.

10. A method of manufacturing a semiconductor device having an active region therein, the method comprising:
forming a semiconductor substrate including a first-conductivity-type region and a second-conductivity-type region on the first-conductivity-type region, to form a pn junction between the first-conductivity-type region and the second-conductivity-type region, the pn junction extending toward an outer periphery of the device from the active region;
forming a trench at a position closer to the outer periphery of the device than is a positon of the active region, to reach a predetermined depth from a first main surface of the semiconductor substrate and terminate the pn junction;
depositing a first oxide film on the first main surface of the semiconductor substrate by a chemical vapor deposition method to embed the first oxide film in the trench;
polishing a surface of the first oxide film to be parallel to the first main surface of the semiconductor substrate, to leave the first oxide film in the trench from the first main surface of the semiconductor substrate;
forming in the trench, a groove that has a width narrower than a width of the trench and that extends in the first oxide film in a depth direction orthogonal to the surface of the first oxide film;
depositing a conductive film on the surface of the first oxide film to embed the conductive film in the groove;
selectively removing the conductive film to leave a portion thereof as a field plate in the first oxide film, the field plate having a first linear portion remaining in the groove, and the second linear portion connected to the first linear portion and extending along the surface of the first oxide film toward the active region; and
depositing a second oxide film on the surface of the first oxide film to cover the field plate.

11. The method according to claim 10, wherein the field plate has a first end at a position facing an upper end of an inner side wall of the trench, and a second end at a position inside the first oxide film and has a protrusion-like shape that protrudes in a direction away from the inner side wall and a bottom of the trench.

12. The method according to claim 10, wherein
the semiconductor substrate is of a first conductivity type and has a resistivity that is at most 145 Ω·cm, and
forming the pn junction includes forming the second-conductivity-type region in a surface layer of the first-conductivity-type region.
